(19) United States
(12) Patent Application Publication
(10) Pub. No.: US 2024/0332468 A1
(43) Pub. Date: Oct. 3, 2024

(54) DISPLAY PANEL, MANUFACTURING METHOD THEREFOR, AND DISPLAY APPARATUS

(71) Applicant: BOE TECHNOLOGY GROUP CO., LTD., Beijing (CN)

(72) Inventors: Kai GUO, Beijing (CN); Weixing LIU, Beijing (CN); Wanpeng TENG, Beijing (CN); Meirong LU, Beijing (CN); Yuwei YAN, Beijing (CN); Chunfang ZHANG, Beijing (CN); Zhiqiang XU, Beijing (CN); Jintao PENG, Beijing (CN); Xinxing WANG, Beijing (CN)

(73) Assignee: BOE TECHNOLOGY GROUP CO., LTD., Beijing (CN)

(21) Appl. No.: 18/667,288

(22) Filed: May 17, 2024

Related U.S. Application Data
(63) Continuation of application No. PCT/CN2023/085611, filed on Mar. 31, 2023.

(51) Int. Cl. H01L 33/58; H01L 27/15; H01L 33/00; H01L 33/50; H01L 33/52

(52) U.S. Cl. CPC H01L 33/58; H01L 27/156; H01L 33/0093; H01L 33/502; H01L 33/507; H01L 33/52

(57) ABSTRACT

A display panel has sub-pixel regions. The display panel includes an optical device layer, an adhesive layer and a light adjustment layer. The optical device layer includes a buffer layer and light-emitting units, a light-emitting unit is located in an opening region of a corresponding sub-pixel region, and the buffer layer is located on a light-exit surface of the light-emitting units. The adhesive layer is located on a side of the buffer layer away from the light-emitting units, a refractive index n2 of the adhesive layer being less than a refractive index n1 of the buffer layer. The light adjustment layer is located on the side of the buffer layer, and is configured such that when light emitted by the light-emitting units enters into the buffer layer, at least part of light with a refraction angle greater than or equal to

$$arc sin \frac{n 2}{n 1}$$

enters the adhesive layer through the light adjustment layer.

### CROSS-REFERENCE TO RELATED APPLICATION

This application is a Bypass Continuation Application of International Patent Application No. PCT/CN2023/085611, filed on Mar. 31, 2023, which is incorporated herein by reference in its entirety.

### TECHNICAL FIELD

The present disclosure relates to the field of display technologies, and in particular, to a display panel, a manufacturing method therefor, and a display apparatus.

### BACKGROUND

With the development of technology and the demand for display, mini light-emitting diodes (Mini LEDs) are the development trend of future display devices. They have advantages that liquid crystal display screens and organic electroluminescent display panels cannot match, such as ultra-high contrast, ultra-high color gamut, high luminous efficiency, high brightness, and low energy consumption.

### SUMMARY

In an aspect, a display panel is provided. The display panel has a plurality of sub-pixel regions, a sub-pixel region including an opening region. The display panel includes an optical device layer, an adhesive layer and a light adjustment layer. The optical device layer includes a buffer layer and a plurality of light-emitting units, a light-emitting unit is located in an opening region of a corresponding sub-pixel region, and the buffer layer is located on a light-exit surface of the plurality of light-emitting units. The adhesive layer is located on a side of the buffer layer away from the plurality of light-emitting units, a refractive index of the adhesive layer being less than a refractive index of the buffer layer. The light adjustment layer is located on the side of the buffer layer proximate to the adhesive layer, the light adjustment layer is configured such that when light emitted by the plurality of light-emitting units enters into the buffer layer, at least part of light with a refraction angle greater than or equal to

$$arc sin \frac{n 2}{n 1}$$

enters the adhesive layer through the light adjustment layer, where n1 is the refractive index of the buffer layer, and n2 is the refractive index of the adhesive layer.

In some embodiments, the light adjustment layer includes a plurality of light adjustment portions, and a light adjustment portion at least partially overlaps a corresponding opening region.

In some embodiments, the light adjustment portion is located in the corresponding opening region.

In some embodiments, the light adjustment layer includes a rough layer.

In some embodiments, the rough layer includes a plurality of scattering particles.

In some embodiments, the buffer layer includes a first surface proximate to the adhesive layer; the first surface includes a plurality of rough regions, and the plurality of rough regions are used as the rough layer.

In some embodiments, a roughness of the rough layer is approximately in a range of 10 nm to 100 nm, inclusive.

In some embodiments, the light adjustment layer includes a light convergence layer.

In some embodiments, the light adjustment layer includes a rough layer and a light convergence layer, and the light convergence layer is located on a side of the rough layer away from the buffer layer.

In some embodiments, a refractive index of the light convergence layer is greater than that of the adhesive layer, and the refractive index of the light convergence layer is less than that of the buffer layer.

In some embodiments, the light convergence layer includes at least one raised portion, and a cross section of a raised portion is triangular; and a base angle α of the raised portion satisfies:

$$arc sin \frac{n 2}{n 1} - arc sin \frac{n 2}{n 3} < α < arc sin \frac{n 2}{n 1} + arc sin \frac{n 2}{n 3} ,$$

where n3 is the refractive index of the light convergence layer.

In some embodiments, a refractive index of the light convergence layer is greater than that of the buffer layer. The light convergence layer includes at least one raised portion, and a cross section of a raised portion is triangular; and a base angle α of the raised portion satisfies:

$$arc sin \frac{n 3}{n 1} - arc sin \frac{n 2}{n 3} < α < arc sin \frac{n 3}{n 1} + arc sin \frac{n 2}{n 3} ,$$

where n3 is the refractive index of the light convergence layer.

In some embodiments, the display panel further includes a light-shielding portion, and the light-shielding portion isolates the plurality of light adjustment portions.

In some embodiments, the display panel further includes an optical conversion layer. The optical conversion layer is located on a side of the adhesive layer away from the light adjustment layer. The optical conversion layer includes a shielding portion and a plurality of color conversion portions, and the shielding portion isolates the plurality of color conversion portions; an orthographic projection of a color conversion portion on the adhesive layer at least partially overlaps an orthographic projection of a corresponding light-emitting unit on the adhesive layer.

In some embodiments, the plurality of color conversion portions include first type color conversion portions and second type color conversion portions; a first type color conversion portion is configured to convert light emitted by a corresponding light-emitting unit into light of a target color; and a second type color conversion portion is configured to allow light emitted by a corresponding light-emitting unit to directly pass through.

In some embodiments, the display panel further includes a color filter layer. The color filter layer is located on a side of the optical conversion layer away from the adhesive layer. The color filter layer includes a plurality of filter units and a black matrix, and the black matrix isolates the plurality of filter units. An orthographic projection of a filter unit on the adhesive layer at least partially overlaps an orthographic projection of a corresponding light-emitting unit on the adhesive layer.

In some embodiments, the orthographic projection of the color conversion portion on the adhesive layer covers the orthographic projection of the filter unit on the adhesive layer.

In another aspect, a manufacturing method for a display panel is provided. The display panel has a plurality of sub-pixel regions, and a sub-pixel region includes an opening region. The manufacturing method includes: providing a sapphire substrate; forming a buffer layer on the sapphire substrate; forming a plurality of light-emitting units on a side of the buffer layer away from the sapphire substrate to form an optical device layer, a light-emitting unit being located in a corresponding sub-pixel region; providing a transfer substrate to bond the plurality of light-emitting units in the optical device layer to the transfer substrate; removing the sapphire substrate; forming a light adjustment layer on a side of the buffer layer away from the plurality of light-emitting units; and providing an adhesive layer to be adhered to a surface of the light adjustment layer away from the buffer layer. The light adjustment layer is configured such that when light emitted by the plurality of light-emitting units enters into the buffer layer, at least part of light with a refraction angle greater than or equal to

$$arc sin \frac{n 2}{n 1}$$

enters the adhesive layer through the light adjustment layer, where n1 is the refractive index of the buffer layer, and n2 is the refractive index of the adhesive layer.

In some embodiments, forming the light adjustment layer on the side of the buffer layer away from the plurality of light-emitting units includes: forming a rough layer having a plurality of scattering particles on the side of the buffer layer away from the plurality of light-emitting units to form the light adjustment layer.

In some embodiments, forming the light adjustment layer on the side of the buffer layer away from the plurality of light-emitting units includes: roughening a first surface of the buffer layer away from the plurality of light-emitting units to form a plurality of rough regions on the first surface, the plurality of rough regions being used as a rough layer, and the rough layer being used to form the light adjustment layer.

In some embodiments, forming the light adjustment layer on the side of the buffer layer away from the plurality of light-emitting units includes: forming a light convergence layer on the side of the buffer layer away from the plurality of light-emitting units to form the light adjustment layer.

In some embodiments, forming the light adjustment layer on the side of the buffer layer away from the plurality of light-emitting units includes: forming a rough layer on the side of the buffer layer away from the plurality of light-emitting units; and forming a light convergence layer on a side of the rough layer away from the plurality of light-emitting units, so as to form the light adjustment layer.

In another aspect, a display apparatus is provided. The display apparatus includes the display panel as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some implementations;

FIG. 3 is a structural diagram of a pixel region in FIG. 2;

FIG. 4 is a sectional diagram of a display panel, in accordance with some embodiments;

FIG. 5 is a curve graph showing brightness of a second sub-pixel region changing with a distance in the direction A1, in accordance with some embodiments;

FIG. 6 is a curve graph showing brightness of a second sub-pixel region changing with a distance in the direction A2, in accordance with some embodiments;

FIG. 7 is a curve graph showing brightness of a first sub-pixel region changing with a distance in the direction A1, in accordance with some embodiments;

FIG. 8 is a curve graph showing brightness of a first sub-pixel region changing with a distance in the direction A2, in accordance with some embodiments;

FIG. 9 is a sectional diagram of another display panel, in accordance with some embodiments;

FIG. 10 is a sectional diagram of yet another display panel, in accordance with some embodiments;

FIG. 11 is a sectional diagram of yet another display panel, in accordance with some embodiments;

FIG. 12 is a sectional diagram of yet another display panel, in accordance with some embodiments;

FIG. 13 is a sectional diagram of yet another display panel, in accordance with some embodiments;

FIG. 14 is a sectional diagram of yet another display panel, in accordance with some embodiments;

FIG. 15 is a sectional diagram of yet another display panel, in accordance with some embodiments;

FIG. 16 is a light path diagram in the region Q in FIG. 15;

FIG. 17 is another light path diagram in the region Q in FIG. 15;

FIG. 18 is yet another light path diagram in the region Q in FIG. 15;

FIG. 19 is yet another light path diagram in the region Q in FIG. 15;

FIG. 20 is a sectional diagram of yet another display panel, in accordance with some embodiments;

FIG. 21 is a sectional diagram of yet another display panel, in accordance with some embodiments;

FIG. 22 is a sectional diagram of yet another display panel, in accordance with some embodiments;

FIG. 23 is a sectional diagram of yet another display panel, in accordance with some embodiments;

FIG. 24 is a sectional diagram of yet another display panel, in accordance with some embodiments;

FIG. 25 is a flowchart of a manufacturing method for a display panel, in accordance with some embodiments;

FIG. 26 is a structural diagram corresponding to some steps in FIG. 25;

FIG. 27 is a structural diagram corresponding to some other steps in FIG. 25;

FIG. 28 is a structural diagram corresponding to step S4 in FIG. 25;

FIG. 29 is another structural diagram corresponding to step S4 in FIG. 25;

FIG. 30 is yet another structural diagram corresponding to step S4 in FIG. 25;

FIG. 31 is yet another structural diagram corresponding to step S4 in FIG. 25; and

FIG. 32 is a structural diagram of some steps in a manufacturing method for a display panel, in accordance with some embodiments.

### DETAILED DESCRIPTION

The technical solutions in embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, the expressions “coupled” and “connected” and derivatives thereof may be used. The term “connected” should be understood in a broad sense. For example, the term “connected” may represent a fixed connection, or a detachable connection, or a one-piece connection; alternatively, the term “connected” may represent a direct connection, or an indirect connection through an intermediate medium. The term “coupled” indicates, for example, that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, and they both include following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

As used herein, the term “if”, depending on the context, is optionally construed as “when” or “in a case where” or “in response to determining” or “in response to detecting”. Similarly, depending on the context, the phrase “if it is determined” or “if [a stated condition or event] is detected” is optionally construed as “in a case where it is determined”, “in response to determining”, “in a case where [the stated condition or event] is detected”, or “in response to detecting [the stated condition or event]”.

The phrase “applicable to” or “configured to” as used herein means an open and inclusive expression, which does not exclude devices that are applicable to or configured to perform additional tasks or steps.

In addition, the phrase “based on” as used herein is meant to be open and inclusive, since a process, step, calculation or other action that is “based on” one or more of the stated conditions or values may, in practice, be based on additional conditions or values exceeding those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It should be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and areas of regions are enlarged for clarity. Variations in shape relative to the accompanying drawings due to, for example, manufacturing technologies and/or tolerances may be envisaged. Therefore, the exemplary embodiments should not be construed as being limited to the shapes of the regions shown herein, but including deviations due to, for example, manufacturing. For example, an etched region shown as a rectangle shape generally has a curved feature. Therefore, the regions shown in the accompanying drawings are schematic in nature, and their shapes are not intended to show actual shapes of regions in a device, and are not intended to limit the scope of the exemplary embodiments.

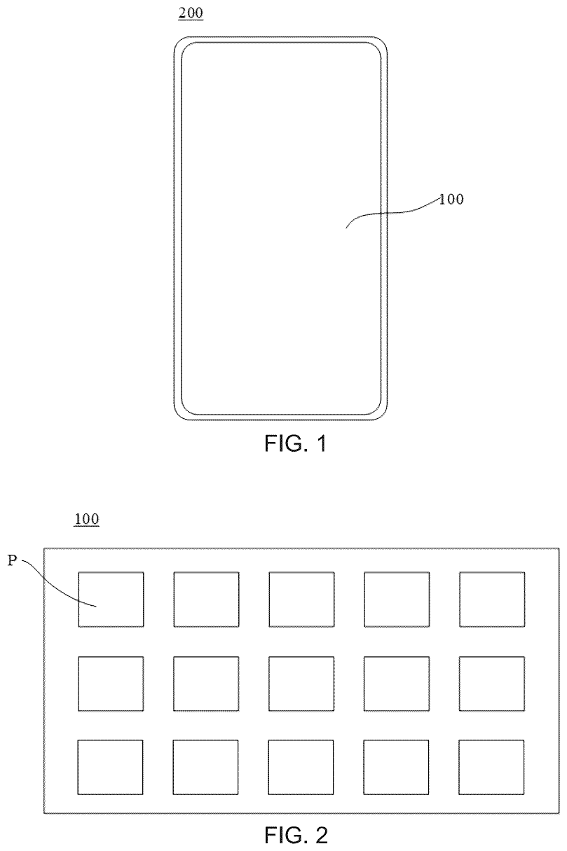

FIG. 1 is a structural diagram of a display apparatus, in accordance with some embodiments. Referring to FIG. 1, some embodiments of the present disclosure provide a display apparatus 200. The display apparatus 200 includes a display panel 100.

For example, the display apparatus 200 further includes a frame, a display driver integrated circuit (IC) and other electronic components.

For example, the display apparatus 200 may be an electroluminescent display apparatus. The electroluminescent display apparatus may be a quantum dot light-emitting diode (QLED) display apparatus.

For example, the display apparatus 200 may be any display apparatus that can display images whether in motion (e.g., videos) or stationary (e.g., static images), and whether textual or graphical. More specifically, it is expected that the display apparatus in the embodiments may be implemented in or associated with a plurality of electronic devices. The plurality of electronic devices may include (but not limited to), for example, mobile telephones, wireless devices, personal data assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat panel displays, computer monitors, car displays (such as odometer displays, etc.), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry).

The following is described by taking a display apparatus with Mini LEDs and quantum dot (QD) as an example.

FIG. 2 is a structural diagram of a display panel, in accordance with some embodiments;

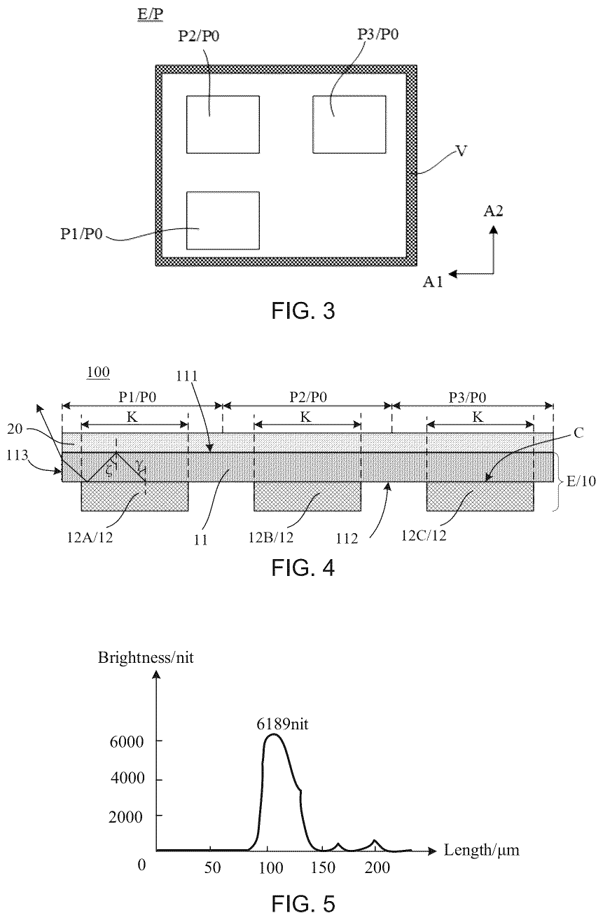

and FIG. 3 is a structural diagram of a pixel region in FIG. 2.

In some embodiments, referring to FIGS. 2 and 3, the display panel 100 includes a plurality of pixel regions P, and a pixel region P includes a plurality of sub-pixel regions P0.

In some examples, sub-pixel regions P0 in the display panel 100 include sub-pixel regions P0 with different light-emitting colors.

For example, the sub-pixel regions P0 are divided into first sub-pixel regions P1, second sub-pixel regions P2 and third sub-pixel regions P3. The first sub-pixel region P1, the second sub-pixel region P2 and the third sub-pixel region P3 emit light of three primary colors. For example, the first sub-pixel region P1 emits red light, the second sub-pixel region P2 emits green light, and the third sub-pixel region P3 emits blue light.

In some examples, a pixel region P includes a plurality of sub-pixel regions P0 for emitting light of different colors.

For example, the pixel region P includes three sub-pixel regions P0 for emitting light of different colors. For example, the pixel region P includes a first sub-pixel region P1, a second sub-pixel region P2 and a third sub-pixel region P3.

FIG. 4 is a sectional diagram of a display panel, in accordance with some embodiments.

Referring to FIG. 4, the sub-pixel region P0 of the display panel 100 includes an opening region K. The light inside the display panel 100 may be emitted through the opening region K to the outside of the display panel 100, so that each sub-pixel region P0 may emit light. Thus, image display of the display panel 100 is achieved.

The display panel 100 further includes an optical device layer 10 and an adhesive layer 20.

The optical device layer 10 includes a plurality of light-emitting units 12. A light-emitting unit 12 can be arranged corresponding to a sub-pixel region P0. For example, the light-emitting unit 12 is arranged in the opening region K of the sub-pixel region P0, so that the light emitted by the light-emitting unit 12 may be emitted through the opening region K to the outside of the display panel 100, achieving the image display of the display panel 100.

In some examples, the light-emitting unit 12 is a blue light-emitting diode (LED) chip. The LED chip can be a micro light-emitting diode (Micro LED) and a mini light-emitting diode (Mini LED).

The following is described by taking the light-emitting unit 12 as the Mini LED as an example.

When the optical device layer 10 in the display panel 100 is formed, the plurality of light-emitting units 12 may generally be formed on a substrate. For example, the light-emitting units 12 are formed on a sapphire substrate.

For example, a semiconductor layer for the light-emitting units 12 is grown on the substrate, and then other film layers for the light-emitting units 12 are formed on the semiconductor layer.

However, since the growth of the semiconductor layer for the light-emitting units 12 on the substrate is heterojunction growth, the lattice-mismatching between the semiconductor layer for the light-emitting units 12 and the sapphire substrate is large, which makes it difficult to directly manufacture the semiconductor layer with high quality on the sapphire substrate. That is, it is difficult to directly manufacture the high-quality light-emitting units 12 on the sapphire substrate.

Thus, the optical device layer 10 can further include a buffer layer 11. The buffer layer 11 is disposed between the semiconductor layer for the light-emitting units 12 and the sapphire substrate, so as to use the buffer layer 11 to reduce defects caused by the heterojunction growth, which is beneficial to improving the quality of the light-emitting units 12.

In some examples, a material of the buffer layer 11 includes GaN. In this case, a refractive index of the buffer layer 11 is approximately 2.4. However, the embodiments of the present disclosure are not limited thereto.

After the light-emitting units 12 are manufactured on the substrate, the substrate can be removed. Subsequently, the adhesive layer 20 can be provided on a side of the buffer layer 11 in the optical device layer 10 away from the light-emitting units 12. Therefore, the adhesive layer 20 may be used to fix the optical device layer 10 with other functional layers in the display panel 100 in the subsequent process. For example, the other functional layers in the display panel 100 include an optical conversion layer, which will be described in detail later.

In some examples, the adhesive layer 20 may be a bonding adhesive layer. For example, a material of the adhesive layer 20 is benzocyclobutene (BCB). In this case, a refractive index of the adhesive layer 20 is approximately 1.56. However, the embodiments of the present disclosure are not limited thereto.

In some examples, the buffer layer 11 is arranged closer to the adhesive layer 20 than the light-emitting units 12, which may prevent the light-emitting units 12 from being in direct contact with the adhesive layer 20 and avoid affecting an electrical connection between an electrode of the light-emitting unit 12 and a connection electrode of the display panel 100.

Based on this, the light-emitting unit 12 may be an inverted Mini LED. Thus, the buffer layer 11 is on the light-exit surface C of the light-emitting units 12.

In general, after the optical device layer 10 is formed, the optical device layer 10 needs to be cut by laser to form independent optical devices E. Subsequently, the independent optical devices E obtained after cutting are transferred into the display panel 100. However, during the cutting process of the optical device layer 10, the buffer layer 11 is cut, which will cause a cutting surface 113 of the buffer layer 11 (i.e., a side surface of each portion of the buffer layer 11 after cutting) to be rough.

In some examples, during the laser cutting process of the optical device layer 10, a light-emitting unit 12 and its corresponding portion of the buffer layer 11 are cut, so that the light-emitting unit 12 and its corresponding portion of the buffer layer 11 form an optical device E. In this case, one light-emitting unit 12 is located in one sub-pixel region P0. That is, one optical device E is located in one sub-pixel region P0. Three optical devices E may be arranged in one pixel region P, and each optical device E is located in one color sub-pixel region P0.

In some other examples, during the laser cutting process of the optical device layer 10, three light-emitting units 12 and their corresponding portion of the buffer layer 11 are cut, so that the three light-emitting units 12 and their corresponding portion of the buffer layer 11 form an optical device E. In this case, one light-emitting unit 12 is located in one sub-pixel region P0, and one optical device E can be located in one pixel region P.

For example, the three light-emitting units 12 in the optical device E are a first light-emitting unit 12A, a second light-emitting unit 12B and a third light-emitting unit 12C. The three light-emitting units 12 are located in the first sub-pixel region P1, the second sub-pixel region P2 and the third sub-pixel region P3, respectively. For example, the first light-emitting unit 12A is located in the first sub-pixel region P1, the second light-emitting unit 12B is located in the second sub-pixel region P2, and the third light-emitting unit 12C is located in the third sub-pixel region P3.

In addition, the optical devices E need to be transferred when the display panel 100 is manufactured. Three light-emitting units 12 are divided into one optical device E, so that the number of optical devices E may be reduced in a case where the number of light-emitting units 12 is constant, and a size of the optical device E may be relatively increased. Based on this, in the process of transferring the optical devices E, the number of optical devices E that need to be transferred may be effectively reduced, thereby effectively reducing the number of transfers, reducing process difficulty, and improving product yield.

FIG. 4 illustrates an example where three light-emitting units 12 and their corresponding portion of the buffer layer 11 form one optical device E.

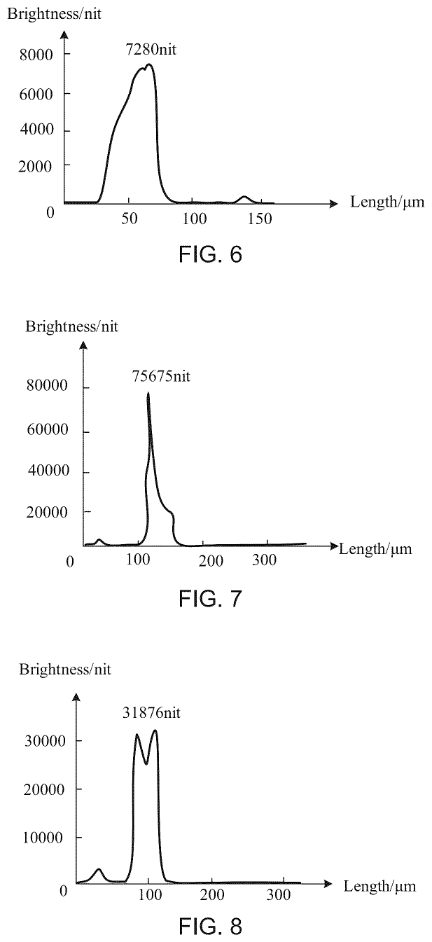

FIG. 5 is a curve graph showing brightness of a second sub-pixel region P2 changing with a distance in the direction A1 (which is shown in FIG. 3), in accordance with some embodiments. FIG. 6 is a curve graph showing brightness of a second sub-pixel region P2 changing with a distance in the direction A2 (which is shown in FIG. 3), in accordance with some embodiments. FIG. 7 is a curve graph showing brightness of a first sub-pixel region P1 changing with a distance in the direction A1, in accordance with some embodiments. FIG. 8 is a curve graph showing brightness of a first sub-pixel region P1 changing with a distance in the direction A2, in accordance with some embodiments. The origin of the coordinate system in FIGS. 5 to 8 can be the center of the sub-pixel region.

As shown in FIG. 4, in general, the refractive index of the adhesive layer 20 is less than the refractive index of the buffer layer 11, and the buffer layer 11 is located between the light-emitting units 12 and the adhesive layer 20; based on this, when the light entering the buffer layer 11 from the light-emitting units 12 is incident onto an interface between the adhesive layer 20 and the buffer layer 11, the light is incident onto a medium with a low refractive index from a medium with a high refractive index. As a result, part of light is prone to total reflection at the interface between the buffer layer 11 and the adhesive layer 20, and the light cannot enter the adhesive layer 20. That is, the buffer layer 11 will cause the part of light emitted by the light-emitting units 12 to be unable to exit through the opening region K in each sub-pixel region P0 of the display panel 100, affecting the brightness of each sub-pixel region P0 of the display panel 100. As a result, the quality of image display of the display panel 100 may be reduced.

In addition, during the cutting process of the optical device layer 10, the buffer layer 11 is cut, which will cause the cutting surface 113 of the buffer layer 11 to be rough. Thus, the part of light totally reflected in the buffer layer 11 will continue to be totally reflected until it is incident onto the cutting surface 113 of the buffer layer 11 and exits through the buffer layer 11. The part of light does not exit through the opening regions K, but rather through the cutting surface 113 of the buffer layer 11 (that is, the part of light exits from the edge V of the optical device E (referring to FIG. 3)), which not only affects the brightness of the light-emitting units 12 in the optical device E (referring to FIGS. 5 to 8), but also causes light leakage at the edge V of the optical device E.

Thus, the quality of image display of the display panel 100 is affected.

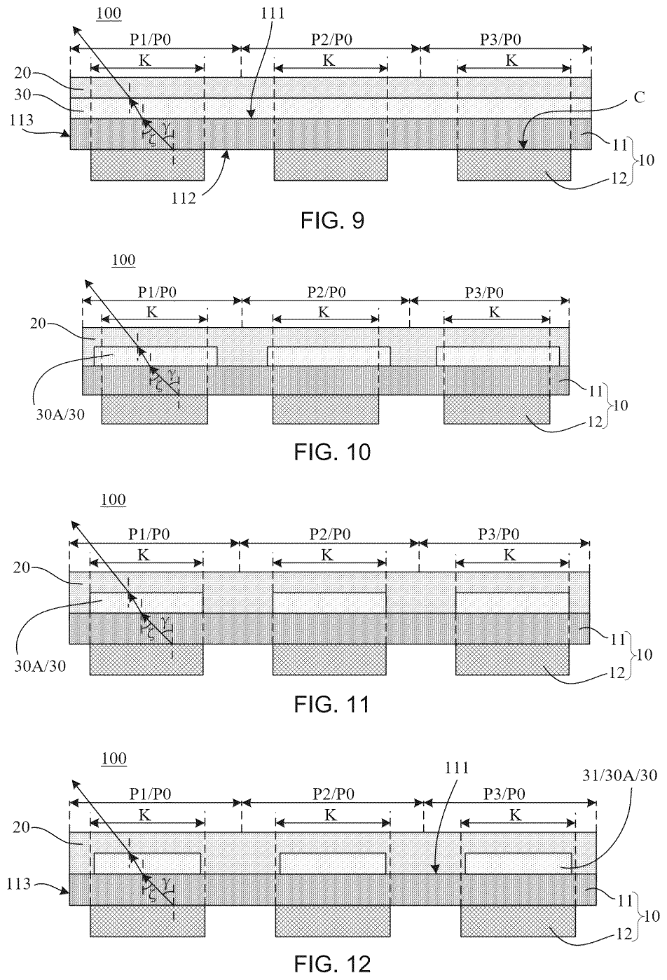

FIG. 9 is a sectional diagram of another display panel, in accordance with some embodiments. FIG. 9 illustrates only three sub-pixel regions P0 in the optical device layer 10 as an example.

Referring to FIG. 9, the display panel 100 provided in some embodiments of the present disclosure further includes a light adjustment layer 30. The light adjustment layer 30 is located on a side of the buffer layer 11 proximate to the adhesive layer 20. The light adjustment layer 30 is configured such that when light emitted by the light-emitting units 12 enters into the buffer layer 11, at least part of light with a refraction angle γ greater than or equal to

$$arc sin \frac{n 2}{n 1}$$

enters the adhesive layer 20 through the light adjustment layer 30. n1 is the refractive index of the buffer layer 11, and n2 is the refractive index of the adhesive layer 20.

It can be understood that, referring to FIG. 4, when the light adjustment layer is not provided, the refraction angle of the light entering the buffer layer 11 from the light-emitting units 12 is γ, and the light continues to move in a direction away from the light-emitting units 12 to be incident onto the adhesive layer 20 (the interface between the buffer layer 11 and the adhesive layer 20). In this case, the incident angle of the light incident onto the adhesive layer 20 is Z. Under normal circumstances, an upper surface 111 and a lower surface 112 of the buffer layer 11 are parallel to each other. Based on this, the refraction angle γ is approximately equal to the incident angle Z.

Moreover, when the light is incident onto the interface between the buffer layer 11 and the adhesive layer 20, light with the incident angle ζ greater than or equal to a critical angle

$$arc sin \frac{n 2}{n 1}$$

will be totally reflected. The light with the incident angle ζ greater than

$$arc sin \frac{n 2}{n 1}$$

will continue to be reflected inside the buffer layer 11 and will not be able to enter the adhesive layer 20, so that the light will not be able to exit upward from the display panel 100. Based on the above description, it can be seen that, the refraction angle γ of the light entering the buffer layer 11 from the light-emitting units 12 is greater than or equal to

$$arc sin \frac{n 2}{n 1} ,$$

total reflection will occur inside the buffer layer 11, and the light will not be able to enter the adhesive layer 20.

After the light adjustment layer 30 is added to the display panel 100, the light adjustment layer 30 can be used to allow at least part of light with the refraction angle γ greater than or equal to

$$arc sin \frac{n 2}{n 1}$$

to enter the adhesive layer 20. That is, at least part of light that would have been totally reflected in the buffer layer 11 can enter the adhesive layer 20 through the light adjustment layer 30, which may mitigate the light leakage problem of the display panel 100 to a certain extent, and in turn, improve the quality of image display of the display panel 100.

In addition, when the light emitted by the light-emitting units 12 enters the buffer layer 11, for light with the refraction angle γ less than

$$arcsin \frac{n 2}{n 1} ,$$

the incident angle ζ of the light incident onto the light adjustment layer 30 is less than the critical angle

$$arcsin \frac{n 2}{n 1} ,$$

so that the light is not able to be totally reflected at the interface between the buffer layer 11 and the light adjustment layer 30, and is able to enter the adhesive layer 20.

Based on this, when the light emitted by the light-emitting units 12 enters the buffer layer 11, for the light with the refraction angle γ less than

$$arcsin \frac{n 2}{n 1} ,$$

and at least part or the light with the refraction angle γ greater than or equal to

$$arcsin \frac{n 2}{n 1} ,$$

they can all continue to enter the adhesive layer 20 and then exit through the opening regions K of the display panel 100, so as to achieve the image display of the display panel 100.

In summary, in the display panel 100 provided in some embodiments of the present disclosure, the light adjustment layer 30 can be disposed on the side of the buffer layer 11 proximate to the adhesive layer 20. The light adjustment layer 30 does not affect the light that has not been totally reflected in the buffer layer 11, so that the light may continue to enter the adhesive layer 20; and the light adjustment layer 30 also allows at least part of the light that would have been totally reflected in the buffer layer 11 to enter the adhesive layer 20, so that the light that is totally reflected in the buffer layer 11 and exits from the cutting surface 113 of the buffer layer 11 may be reduced. Thus, it may be possible to help increase the brightness of each sub-pixel region P0 of the display panel 100, and prevent light leakage of each pixel region P (optical device E) of the display panel 100, thereby improving the quality of image display of the display panel 100.

It should be noted that, for light adjustment layers 30 with different structures, different quantities of light with the refraction angle greater than or equal to

$$arcsin \frac{n 2}{n 1}$$

may be allowed to enter the adhesive layer 20. When the light adjustment layers 30 with different structures are introduced below, the principle of solving the problem will be described in detail, as well as the quantity of light entering the adhesive layer 20, with the refraction angle γ greater than or equal to

$$arcsin \frac{n 2}{n 1} .$$

FIG. 10 is a sectional diagram of yet another display panel, in accordance with some embodiments. FIG. 11 is a sectional diagram of yet another display panel, in accordance with some embodiments. FIG. 12 is a sectional diagram of yet another display panel, in accordance with some embodiments.

As shown in FIGS. 10 to 12, the light adjustment layer 30 includes a plurality of light adjustment portions 30A, and a light adjustment portion 30A at least partially overlaps an opening region K.

Since a light-emitting unit 12 is located in the opening region K in a sub-pixel region P0, the light emitted by the light-emitting unit 12 exits through the opening region K, and the sub-pixel region P0 emits light. Based on this, the light adjustment layer 30 is patterned into the plurality of light adjustment portions 30A, and the light adjustment portion 30A is arranged to at least partially overlap the opening region K, so that the light adjustment portion 30A overlapping with the opening region K is used to allow at least part of light, which is emitted by the light-emitting unit 12 and has the refraction angle γ greater than or equal to

$$arcsin \frac{n 2}{n 1} ,$$

to enter the adhesive layer 20. Thus, the problem of total reflection of the light emitted by the light-emitting unit 12 is mitigated, and the light emitted by the light-emitting unit 12 can exit from the opening region K of the display panel 100 to ensure the quality of image display of the display panel 100.

As for “the light adjustment portion 30A at least partially overlaps the opening region K”, the following situations are included.

In the first situation, with continued reference to FIG. 10, a size of the light adjustment portion 30A is larger than that of the opening region K, and the light adjustment portion 30A covers the opening region K. In this case, the light adjustment portion 30A can better cover a portion of the buffer layer 11 overlapping with the opening region K, so that the light adjustment portion 30A is used to allow at least part of light, which is emitted by the light-emitting unit 12 and has the refraction angle γ greater than or equal to

$$arcsin \frac{n 2}{n 1} ,$$

to enter the adhesive layer 20. Thus, the problem of total reflection of the light emitted by the light-emitting unit 12 at the interface between the portion of the buffer layer 11 and the light adjustment portion 30A in the opening region K is mitigated, and the light leakage of each pixel region P (optical device E) of the display panel 100 is mitigated, which is beneficial to increasing the brightness of each sub-pixel region P0 of the display panel 100, and improving the quality of image display of the display panel 100.

In the second situation, with continued reference to FIG. 11, the light adjustment portion 30A completely overlaps the opening region K. In this case, the light adjustment portion 30A can cover a portion of the buffer layer 11 overlapping with the opening region K, so that the light adjustment portion 30A is used to allow at least part of light, which is emitted by the light-emitting unit 12 and has the refraction angle γ greater than or equal to

$$arcsin \frac{n 2}{n 1} ,$$

to enter the adhesive layer 20. Thus, the problem of total reflection of the light emitted by the light-emitting unit 12 at the interface between the portion of the buffer layer 11 and the light adjustment portion 30A in the opening region K is mitigated. In addition, it may also be possible to prevent the light processed by the light adjustment portion 30A from entering the opening regions K of other sub-pixel regions P0 adjacent to the sub-pixel region P0 (which results in problems such as color shift) due to the size of the light adjustment portion 30A corresponding to the opening region K of the sub-pixel region P0 being too large.

In the third situation, with continued reference to FIG. 12, the light adjustment part 30A is located in the opening region K. Based on this, the light adjustment portion 30A in the opening region K can be retracted by a certain distance, so that the light adjustment portion 30A may basically cover a portion of the buffer layer 11 overlapping with the opening region K. Thus, the light adjustment portion 30A is used to allow at least part of light, which is emitted by the light-emitting unit 12 and has the refraction angle γ greater than or equal to

$$arcsin \frac{n 2}{n 1} ,$$

to enter the adhesive layer 20, and the problem of total reflection of the light emitted by the light-emitting unit 12 at the interface between the portion of the buffer layer 11 and the light adjustment portion 30A in the opening region K is mitigated. In addition, the size of the light adjustment portion 30A corresponding to the opening region K of the sub-pixel region P0 may be optimized. It may be possible to prevent the light processed by the light adjustment portion 30A from entering the opening regions K of other sub-pixel regions P0 adjacent to the sub-pixel region P0 (which results in problems such as color shift) due to the size of the light adjustment portion 30A corresponding to the opening region K of the sub-pixel region P0 being too large.

The following is described by taking the third situation where the light adjustment part 30A is located in the opening region K as an example.

In some embodiments, referring to FIG. 12, the light adjustment layer 30 includes a rough layer 31.

The light adjustment layer 30 includes the rough layer 31. A first surface 111, away from the light-emitting units 12, of the buffer layer 11 is in contact with the rough layer 31. When the light emitted by the light-emitting units 12 is incident onto the interface between the buffer layer 11 and the light adjustment layer 30, it is equivalent to the light being incident onto the interface between the buffer layer 11 and the rough layer 31. Since the rough layer 31 has a certain degree of roughness, the light may be scattered, thereby reducing the probability of total reflection of the light at the interface between the buffer layer 11 and the rough layer 31. Therefore, the rough layer 31 may be used to allow a large quantity or even all the light with the refraction angle γ greater than or equal to

$$arcsin \frac{n 2}{n 1}$$

to enter the adhesive layer 20. That is, a large quantity or even all the light that would have been totally reflected in the buffer layer 11 may be allowed to enter the adhesive layer 20, which may reduce the light that is totally reflected in the buffer layer 11 and exits from the cutting surface 113 of the buffer layer 11. Thus, it may be possible to help increase the brightness of each sub-pixel region P0 of the display panel 100, and prevent light leakage of each pixel region P (optical device E) of the display panel 100, thereby improving the quality of image display of the display panel 100.

In some examples, the rough layer 31 includes a plurality of rough portions. That is, the light adjustment portion 30A is a rough portion. Thus, the rough portion can be arranged to at least partially overlap the opening region K.

Since a light-emitting unit 12 is located in the opening region K in a sub-pixel region P0, the light emitted by the light-emitting unit 12 exits through the opening region K, and the sub-pixel region P0 emits light. Based on this, the rough layer 31 is patterned into the plurality of rough portions, and the rough portion is arranged to at least partially overlap the opening region K, so that the rough portion overlapping with the opening region K is used to make the light emitted by the light-emitting unit 12 scattered, and the total reflection of the light emitted by the light-emitting unit 12 at the interface between the buffer layer 11 and the rough portion is destroyed. Thus, the light emitted by the light-emitting unit 12 can exit from the opening region K of the display panel 100 to ensure the quality of image display of the display panel 100.

As for “the rough portion at least partially overlaps the opening region K”, the following situations are included.

In the first situation, a size of the rough portion is larger than that of the opening region K, and the rough portion covers the opening region K. In this case, the rough portion can better cover a portion of the buffer layer 11 overlapping with the opening region K, so that the rough portion is used to make the light emitted by the light-emitting unit 12 scattered. Thus, the problem of total reflection of the light emitted by the light-emitting unit 12 at the interface between the buffer layer 11 and the rough portion in the opening region K is mitigated, and the light leakage of each pixel region P (optical device E) of the display panel 100 is mitigated, which is beneficial to increasing the brightness of each sub-pixel region P0 of the display panel 100, and improving the quality of image display of the display panel 100.

In the second situation, the rough portion completely overlaps the opening region K. In this case, the rough portion can cover a portion of the buffer layer 11 overlapping with the opening region K, so that the rough portion is used to make the light emitted by the light-emitting unit 12 scattered. Thus, the problem of total reflection of the light emitted by the light-emitting unit 12 at the interface between the buffer layer 11 and the rough portion in the opening region K is mitigated. In addition, it may also be possible to prevent the light scattered by the rough portion from entering the opening regions K of other sub-pixel regions P0 adjacent to the sub-pixel region P0 (which results in problems such as color shift) due to the size of the rough portion corresponding to the opening region K of the sub-pixel region P0 being too large.

In the third situation, the rough portion is located in the opening region K. Based on this, the rough portion in the opening region K can be retracted by a certain distance, so that the rough portion may basically cover a portion of the buffer layer 11 overlapping with the opening region K. Thus, the rough portion is used to make the light emitted by the light-emitting unit 12 scattered, and the problem of total reflection of the light emitted by the light-emitting unit 12 at the interface between the buffer layer 11 and the rough portion in the opening region K is mitigated. In addition, the size of the rough portion corresponding to the opening region K of the sub-pixel region P0 may be optimized. It may be possible to prevent the light scattered by the rough portion from entering the opening regions K of other sub-pixel regions P0 adjacent to the sub-pixel region P0 (which results in problems such as color shift) due to the size of the rough portion corresponding to the opening region K of the sub-pixel region P0 being too large.

In some embodiments, with continued reference to FIG. 12, the roughness of the rough layer 31 is approximately in a range of 10 nm to 100 nm, inclusive.

When the roughness of the rough layer 31 is equal to or close to 10 nm, the roughness of the rough layer 31 is relatively low. Thus, it may be beneficial to simplify the process difficulty of manufacturing the rough layer 31. In addition, the rough layer 31 may also meet the requirement of destroying the total reflection and making the light scattered. When the roughness of the rough layer 31 is equal to or close to 100 nm, the roughness of the rough layer 31 is relatively high. Thus, the rough layer 31 may more effectively destroy the total reflection of light and make the light scattered. In addition, it may also meet the existing process difficulty of forming the rough layer 31.

In some examples, the roughness of the rough layer 31 is approximately in a range of 30 nm to 100 nm, inclusive. Alternatively, the roughness of the rough layer 31 is approximately in a range of 50 nm to 100 nm, inclusive.

The roughness of the rough layer 31 may be made higher, so that the rough layer 31 may more effectively destroy the total reflection of light and make the light scattered. Thus, it is beneficial to reduce the probability of the total reflection at the interface between the buffer layer 11 and the rough layer 31 by using the rough layer 31. And the light leakage of each pixel region P (optical device E) of the display panel 100 is prevented, so as to improve the quality of image display of the display panel 100.

In some examples, the roughness of the rough layer 31 is approximately any one of 10 nm, 20 nm, 30 nm, 40 nm, 50 nm, 60 nm, 70 nm, 80 nm, 90 nm, or 100 nm. However, the embodiments of the present disclosure are not limited thereto.

In some embodiments, on the basis that the light adjustment layer 30 includes the rough layer 31, for “the light adjustment layer 30 is located on the side of the buffer layer 11 proximate to the adhesive layer 20”, which means that the rough layer 31 is located on the side of the buffer layer 11 proximate to the adhesive layer 20, and may include the following situations.

In the first situation, the rough layer 31 is located between the buffer layer 11 and the adhesive layer 20.

In the second situation, the rough layer 31 is a surface of the buffer layer 11 proximate to the adhesive layer 20. Since the first surface of the buffer layer 11 proximate to the adhesive layer 20 is also located on the side of the buffer layer 11 proximate to the adhesive layer 20, it can be understood that the rough layer 31 is located on the side of the buffer layer 11 proximate to the adhesive layer 20.

The first situation is first introduced below with reference to the accompanying drawings.

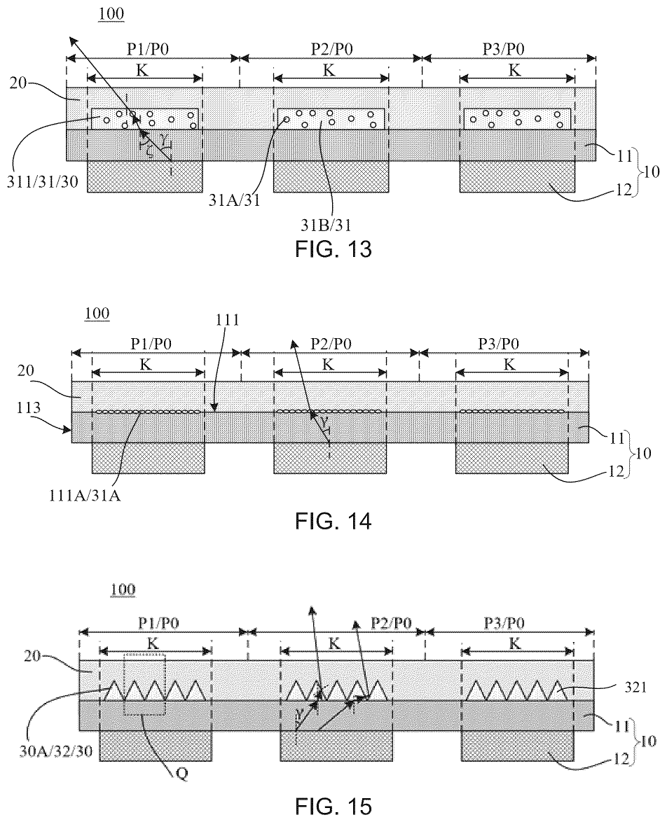

FIG. 13 is a sectional diagram of yet another display panel, in accordance with some embodiments.

In some other embodiments, referring to FIG. 13, the rough layer 31 includes a plurality of scattering particles 31A.

The rough layer 31 is provided with the plurality of scattering particles 31A, so that the plurality of scattering particles 31A may be used to increase the probability of scattering when the light emitted by the light-emitting unit 12 enters the rough layer 31, and the plurality of scattering particles 31A may be used to better reduce the probability of total reflection of light.

Based on this, the plurality of scattering particles 31A in the rough layer 31 may be used to effectively mitigate the problem of total reflection of the light emitted by the light-emitting unit 12 at the interface between the buffer layer 11 and the light adjustment layer 30 (rough layer 31). Thus, it is beneficial to prevent the light leakage of each pixel region P (optical device E) of the display panel 100, thereby improving the quality of image display of the display panel 100.

In some examples, the rough layer 31 includes a substrate 31B and the plurality of scattering particles 31A distributed in the substrate 31B.

For example, the plurality of scattering particles 31A are evenly distributed in the substrate 31B. The plurality of scattering particles 31A in the rough layer 31 may be evenly distributed, so that each position of the rough layer 31 may use the scattering particles 31A to scatter the light incident onto the interface of the buffer layer 11 and the light adjustment layer 30 (rough layer 31). Thus, the quantity of light totally reflected is reduced, so as to prevent the light leakage of each pixel region P (optical device E) of the display panel 100 and improve the quality of image display of the display panel 100.

In some examples, a ratio of a refractive index of the scattering particles 31A to a refractive index of the substrate 31B is approximately in a range of 0.91 to 0.97, inclusive. Alternatively, the ratio of the refractive index of the scattering particles 31A to the refractive index of the substrate 31B is approximately in a range of 1.03 to 1.09, inclusive.

That is, the refractive index of the scattering particles 31A can be greater than the refractive index of the substrate 31B, or the refractive index of the scattering particles 31A can be less than the refractive index of the substrate 31B, as long as it is ensured that a difference between the refractive index of the scattering particles 31A and the refractive index of the substrate 31B is in a range of 0.03 to 0.09, inclusive.

Based on this, the difference between the refractive index of the scattering particles 31A and the refractive index of the substrate 31B may be prevented from being too small, and the diffusivity and transmittance of the rough layer 31 may be both relatively good. The plurality of scattering particles 31A in the rough layer 31 may be used to effectively mitigate the problem of total reflection of the light emitted by the light-emitting unit 12 at the interface between the buffer layer 11 and the light adjustment layer 30 (rough layer 31). Thus, it is beneficial to prevent the light leakage of each pixel region P (optical device E) of the display panel 100, thereby improving the quality of image display of the display panel 100.

In some examples, the ratio of the sum of volumes of the plurality of scattering particles 31A to the volume of the substrate 31B is less than or equal to 2%. Based on this, it may be possible to prevent the concentration of the scattering particles 31A in the substrate 31B from being too high, and prevent the number of the scattering particles 31A in the substrate 31B from being too high. The high concentration will result in the haze of the rough layer 31 being relatively high and the transmittance of the rough layer 31 being too low, and thus the transmittance of light in the display panel 100 will be affected, thereby affecting the brightness of the display panel 100 and the quality of image display of the display panel 100.

In some examples, the scattering particles 31A are made of an organic material. For example, the scattering particles 31A are made of at least one of acrylic acid type, organic silicon type, or polyethylene type. For example, the scattering particles 31A are made of acrylic acid type and organic silicon type.

In some other examples, the scattering particles 31A are made of an inorganic material. For example, the scattering particles 31A are made of at least one of nanometer barium sulfate, silicon dioxide, or calcium carbonate.

In some examples, the substrate 31B is made of a material with a high transmittance.

For example, the substrate 31B is made of at least one of polymethyl methacrylate (PMMA), polystyrene (PS), or polycarbonate (PC).

The above embodiments describe the first position of the rough layer 31 with reference to the accompanying drawings. The second position of the rough layer 31 will be introduced below with reference to the accompanying drawings.

FIG. 14 is a sectional diagram of yet another display panel, in accordance with some embodiments.

In some embodiments, referring to FIG. 14, the buffer layer 11 includes the first surface 111 proximate to the adhesive layer 20. The first surface 111 includes a plurality of rough regions 111A, and portions of the first surface 111 at the plurality of rough regions 111A are used as the rough layer 31. FIG. 14 only represents the rough region 111A with multiple elliptical patterns, but does not represent the roughness of the rough region 111A and the structure of the rough region 111A.

The first surface 111, proximate to the adhesive layer 20, included in the buffer layer 11 may be roughened, so that the first surface 111 forms the plurality of rough regions 111A. By using the portions of the first surface 111 at the plurality of rough regions 111A as the rough layer 31, the plurality of rough regions 111A formed by the first surface 111 may be used to scatter a large quantity or even all of the light that would have been totally reflected in the buffer layer 11, so as to make the light enter the adhesive layer 20. That is, the light that is totally reflected in the buffer layer 11 and exits from the cutting surface 113 of the buffer layer 11 may be reduced. Thus, it may be possible to help increase the brightness of each sub-pixel region P0 of the display panel 100, and prevent light leakage of each pixel region P (optical device E) of the display panel 100, thereby improving the quality of image display of the display panel 100.

In addition, since the portions of the first surface 111 at the plurality of rough regions 111A are used as the rough layer 31, after the first surface 111 of the buffer layer 11 proximate to the adhesive layer 20 is roughened, there is no need to add an independent rough layer 31 in the display panel 100, which not only helps save resources, but also helps make the display panel 100 have a light weight and a small thinness.

In some examples, with continued reference to FIG. 14, the roughness of the portions of the first surface 111 at the rough regions 111A is set to be approximately in a range of 10 nm to 100 nm, inclusive.

When the roughness of the portions of the first surface 111 at the rough regions 111A is equal to or close to 10 nm, the roughness of the portions of the first surface 111 at the rough regions 111A is relatively low. Thus, it may be beneficial to simplify the roughening process of the first surface 111 of the buffer layer 11 proximate to the adhesive layer 20, and the portions of the first surface 111 at the rough regions 111A may also meet the requirement of destroying the total reflection and making the light scattered. When the roughness of the portions of the first surface 111 at the rough regions 111A is equal to or close to 100 nm, the roughness of the portions of the first surface 111 at the rough regions 111A is relatively high. Thus, the portions of the first surface 111 at the rough regions 111A may more effectively destroy the total reflection of light and make the light scattered. In addition, the existing accuracy requirement for roughening the first surface 111 may also met.

FIG. 15 is a sectional diagram of yet another display panel, in accordance with some embodiments.

In some embodiments, referring to FIG. 15, the light adjustment layer 30 includes a light convergence layer 32.

The light adjustment layer 30 includes the light convergence layer 32. The first surface 111, away from the light-emitting units 12, of the buffer layer 11 is in contact with the light convergence layer 32. When the light emitted by the light-emitting units 12 is incident onto the interface between the buffer layer 11 and the light adjustment layer 30, it is equivalent to the light being incident onto the interface between the buffer layer 11 and the light convergence layer 32. The refractive index and structure of the light convergence layer 32 may be set to allow part of light with the refraction angle γ is greater than or equal to

$$arcsin \frac{n 2}{n 1}$$

to enter the adhesive layer 20. That is, the part of light that would have been totally reflected in the buffer layer 11 may enter the adhesive layer 20, which may reduce the light that is totally reflected in the buffer layer 11 and exits from the cutting surface 113 of the buffer layer 11. Thus, it may be possible to help increase the brightness of each sub-pixel region P0 of the display panel 100, and prevent light leakage of each pixel region P (optical device E) of the display panel 100, thereby improving the quality of image display of the display panel 100. The refractive index and structure of the light convergence layer 32 will be described in detail below with reference to the accompanying drawings.

In some examples, the light convergence layer 32 includes a plurality of light convergence portions. That is, the light adjustment portion 30A is a light convergence portion, and the light convergence portion at least partially overlaps the opening region K.

Since a light-emitting unit 12 is located in the opening region K in a sub-pixel region P0, the light emitted by the light-emitting unit 12 exits from the opening region K, and the sub-pixel region P0 emits light. Based on this, the light convergence layer 32 is patterned into the plurality of light convergence portions, and the light convergence portion at least partially overlaps the opening region K, so that the light convergence portion overlapping with the opening region K is used to allow more light emitted by the light-emitting unit 120 with a relatively large refraction angle γ to enter the adhesive layer 20 without the total reflection. Thus, the problem of total reflection of the light emitted by the light-emitting unit 12 at the interface between the buffer layer 11 and the light convergence portion may be mitigated to a certain extent, and the light emitted by the light-emitting unit 12 may exit from the opening region K of the display panel 100 to ensure the quality of image display of the display panel 100.

As for “the light convergence portion at least partially overlaps the opening region K”, the following situations are included.

In the first situation, a size of the light convergence portion is larger than that of the opening region K, and the light convergence portion covers the opening region K. In this case, the light convergence portion can better cover a portion of the buffer layer 11 overlapping with the opening region K, so that the light convergence portion is used to allow more light emitted by the light-emitting unit 120 with a relatively large refraction angle γ to enter the adhesive layer 20 without the total reflection. Thus, the problem of total reflection of the light emitted by the light-emitting unit 12 at the interface between the buffer layer 11 and the light convergence portion in the opening region K is mitigated, and the light leakage of each pixel region P (optical device E) of the display panel 100 is mitigated, which help increase the brightness of each sub-pixel region P0 of the display panel 100, and improve the quality of image display of the display panel 100.

In the second situation, the light convergence portion completely overlaps the opening region K. In this case, the light convergence portion can cover a portion of the buffer layer 11 overlapping with the opening region K, so that the light convergence portion is used to allow more light emitted by the light-emitting unit 120 with a relatively large refraction angle γ to enter the adhesive layer 20 without the total reflection. Thus, the problem of total reflection of the light emitted by the light-emitting unit 12 at the interface between the buffer layer 11 and the light convergence portion in the opening region K is mitigated. In addition, it may also be possible to prevent the light refracted by the light convergence portion from entering the opening regions K of other sub-pixel regions P0 adjacent to the sub-pixel region P0 (which results in problems such as color shift) due to the size of the light convergence portion corresponding to the opening region K of the sub-pixel region P0 being too large.

In the third situation, the light convergence portion is located in the opening region K. Based on this, the light convergence portion in the opening region K can be retracted by a certain distance, so that the light convergence portion may basically cover a portion of the buffer layer 11 overlapping with the opening region K. Thus, the light convergence portion is used to allow more light emitted by the light-emitting unit 120 with a relatively large refraction angle γ to be refracted into the adhesive layer 20, and the problem of total reflection of the light emitted by the light-emitting unit 12 at the interface between the buffer layer 11 and the light convergence portion in the opening region K is mitigated. In addition, the size of the light convergence portion corresponding to the opening region K of the sub-pixel region P0 may be optimized. It may be possible to prevent the light refracted by the light convergence portion from entering the opening regions K of other sub-pixel regions P0 adjacent to the sub-pixel region P0 (which results in problems such as color shift) due to the size of the light convergence portion corresponding to the opening region K of the sub-pixel region P0 being too large.

The following is described by taking the third situation where the light convergence portion is located in the opening region K as an example.

As for how to adjust the refractive index and structure of the light convergence layer 32 to allow part of light with the refraction angle γ greater than or equal

$$arcsin \frac{n 2}{n 1}$$

to enter the adhesive layer 20, the refractive index of the light convergence layer 32 will be introduced below with reference to the accompanying drawings.

In some embodiments, referring to FIG. 15, the refractive index of the light convergence layer 32 is greater than or equal to the refractive index of the adhesive layer 20, and the refractive index of the light convergence layer 32 is less than or equal to the refractive index of the buffer layer 11.

The light convergence layer 32 is arranged between the buffer layer 11 and the adhesive layer 20, and the refractive index of the light convergence layer 32 is set to be between the refractive index of the buffer layer 11 and the refractive index of the adhesive layer 20. The light convergence layer 32 is equivalent to a transition layer between the buffer layer 11 and the adhesive layer 20.

The critical angle, at which the light that is emitted by the light-emitting unit 12 and is incident onto the interface between the buffer layer 11 and the light convergence layer 32 is totally reflected, is

$$arcsin \frac{n 3}{n 1} ,$$

where n3 is the refractive index of the light convergence layer 32. Since the refractive index n3 of the light convergence layer 32 is greater than the refractive index n2 of the adhesive layer 20, the critical angle

$$arcsin \frac{n 3}{n 1}$$

of total reflection at the interface between the buffer layer 11 and the light convergence layer 32 is greater than the critical angle

$$arcsin \frac{n 2}{n 1}$$

of total reflection at the interface between the buffer layer 11 and the adhesive layer 20. Thus, it may be understood that, after adding the light convergence layer 32 between the buffer layer 11 and the adhesive layer 20 of the display panel 100, the critical angle of total reflection at the interface between the first surface 111 of the buffer layer 11 and its adjacent film layer is relatively increased. Furthermore, more light with the refraction angle greater than or equal to

$$arcsin \frac{n 2}{n 1}$$

may be refracted at the interface between the buffer layer 11 and the light convergence layer 32, so as to enter the light convergence layer 32.

Moreover, since the refractive index of the light convergence layer 32 is less than the refractive index of the buffer layer 11, the critical angle

$$arcsin \frac{n 2}{n 3}$$

of total reflection at the interface between the light convergence layer 32 and the adhesive layer 20 may be greater than the critical angle

$$arcsin \frac{n 2}{n 1}$$

of total reflection at the interface between the buffer layer 11 and the adhesive layer 20. Therefore, after the light convergence layer 32 is added between the buffer layer 11 and the adhesive layer 20 of the display panel 100, as for the critical angle of total reflection at the interface between the light convergence layer 32 and the adhesive layer 20, and the critical angle of total reflection at the interface between the light convergence layer 32 and the buffer layer 11, they are both increased to a certain extent relative to the critical angle of total reflection at the interface between the buffer layer 11 and the adhesive layer 20.

Based on this, more light with the refraction angle greater than or equal to

$$arcsin \frac{n 2}{n 1}$$

may be refracted at the interface between the buffer layer 11 and the light convergence layer 32, so as to enter the light convergence layer 32, and then enter the adhesive layer 20 through the refraction of the light convergence layer 32. Thus, part of light that would have been totally reflected in the buffer layer 11 may enter the adhesive layer 20, and light that is totally reflected in the buffer layer 11 and exits from the cutting surface 113 of the buffer layer 11 may be reduced. Therefore, it may be possible to help increase the brightness of each sub-pixel region P0 of the display panel 100, and prevent light leakage of each pixel region P (optical device E) of the display panel 100, thereby improving the quality of image display of the display panel 100.

In some embodiments, the light convergence portion is made of a transparent material. For example, the material of the light convergence portion includes any one of rubber, silicon nitride, silicon oxide, or silica gel. However, some embodiments of the present disclosure are not limited thereto.

In some examples, as shown in FIG. 15 the light convergence portion includes at least one raised portion 321. The cross section of the raised portion 321 may be semicircular or triangular. However, some embodiments of the present disclosure are not limited thereto, as long as the raised portion 321 has a structure protruding toward the adhesive layer 20.

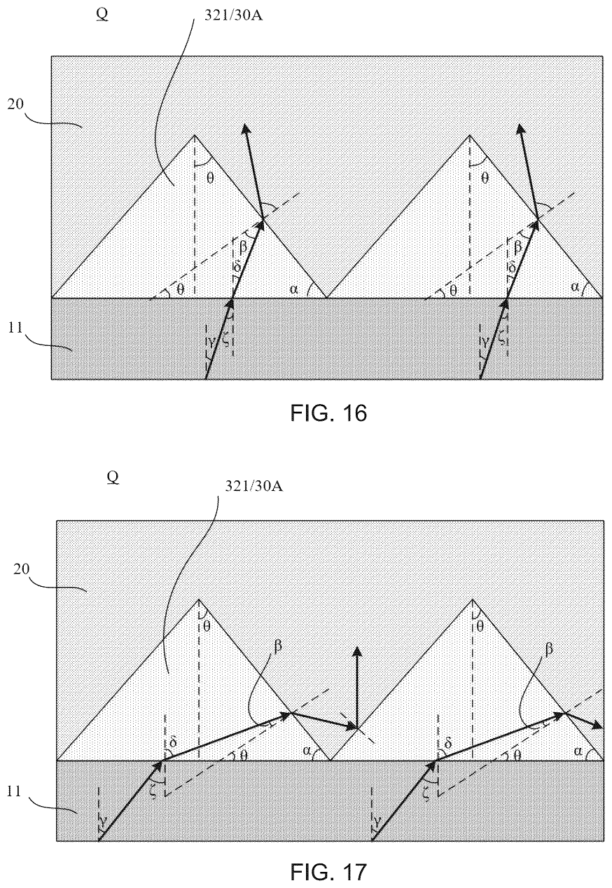

FIG. 16 is a light path diagram in the region Q in FIG. 15. FIG. 17 is another light path diagram in the region Q in FIG. 15.

In some embodiments, referring to FIGS. 16 and 17, in the case where the refractive index n3 of the light convergence layer 32 is greater than the refractive index n2 of the adhesive layer 20, and the refractive index n3 of the light convergence layer 32 is less than the refractive index n1 of the buffer layer 11 (i.e., n1>n3>n2), the light convergence portion can include at least one raised portion 321, the cross section of the raised portion 321 is triangular, and the base angle α of the raised portion 321 satisfies

$$arcsin \frac{n 2}{n 1} - arcsin \frac{n 2}{n 3} < α < arcsin \frac{n 2}{n 1} + arcsin \frac{n 2}{n 3} ,$$

where n3 is the refractive index of the light convergence layer 32.

Since the refractive index n3 of the light convergence layer 32 is less than the refractive index n1 of the buffer layer 11, in order to prevent the total reflection at the interface between the buffer layer 11 and the light convergence layer 32, it is necessary to set the incident angle ζ of light in the buffer layer 11 that is incident onto the raised portion 321 as

$$ζ < arcsin \frac{n 3}{n 1} .$$

With continued reference to FIG. 16, the relationship between various angles in the raised portion 321 can satisfy: 90°−δ=θ+β=90°−α+βδ. δ is the refraction angle of the light refracted into the raised portion 321, B is the incident angle when the light in the raised portion 321 is incident onto the side face of the raised portion 321, a is the base angle of the raised portion 321, and θ is the supplementary angle of the base angle α of the raised portion 321.

Since the refractive index n3 of the light convergence layer 32 is greater than the refractive index n2 of the adhesive layer 20, the incident angle β needs to be set smaller than the critical angle

$$arcsin \frac{n 2}{n 3} .$$

That is, the maximum value of the incident angle β approaches

$$arcsin \frac{n 2}{n 3} .$$

Moreover, in order to ensure that at least part of light with the refraction angle γ greater than or equal to

$$arcsin \frac{n 2}{n 1}$$

enters the adhesive layer 20, the incident angle ζ needs to be set as

$$ζ > arcsin \frac{n 2}{n 1} .$$

In addition, when the light enters the light convergence layer 32 with the low refractive index from the buffer layer 11 with the high refractive index, the refraction angle δ is greater than the incident angle ζ, and then it can be known that the refraction angle

$$δ > arcsin \frac{n 2}{n 1} .$$

As described above, it can be known that the maximum range of a can be

$$arcsin \frac{n 2}{n 1} + arcsin \frac{n 2}{n 3} , i . e . , α < arcsin \frac{n 2}{n 1} + arcsin \frac{n 2}{n 3} .$$

With continued reference to FIG. 17, the relationship between various angles in the raised portion 321 can satisfy: 90°−δ=θ−β=90°−α−β, α=δ−β. δ is the refraction angle of the light refracted into the raised portion 321, β is the incident angle when the light in the raised portion 321 is incident onto the side face of the raised portion 321, α is the base angle of the raised portion 321, and θ is the supplementary angle of the base angle α of the raised portion 321.

Since the refractive index n3 of the light convergence layer 32 is greater than the refractive index n2 of the adhesive layer 20, the incident angle β needs to be set smaller than the critical angle

$$arcsin \frac{n 2}{n 3} , i . e . , β < arcsin \frac{n 2}{n 3} .$$

Moreover, in order to ensure that at least part of light with the refraction angle γ greater than or equal to

$$a r c s m \frac{n 2}{n 1}$$

enters the adhesive layer 20, the incident angle ζ needs to be set as

$$ζ > arcsin \frac{n 2}{n 1} .$$

In addition, when the light enters the light convergence layer 32 with the low refractive index from the buffer layer 11 with the high refractive index, the refraction angle δ is greater than the incident angle ζ, and thus it can be known that the refraction angle

$$δ > arcsin \frac{n 2}{n 1} .$$

Based on

$$β < arcsin \frac{n 2}{n 3} and δ > arcsin \frac{n 2}{n 1} ,$$

it can be known

$$α > arcsin \frac{n 2}{n 1} - arcsin \frac{n 2}{n 3} .$$

In summary, in the case where the base angle α of the raised portion 321 satisfies

$$arcsin \frac{n 2}{n 1} - arcsin \frac{n 2}{n 3} < α < arcsin \frac{n 2}{n 1} + arcsin \frac{n 2}{n 3} ,$$

at least part of light with the refraction angle γ greater than or equal to

$$arcsin \frac{n 2}{n 1}$$

enters the adhesive layer 20, and the incident angle ß can be less than the critical angle

$$arcsin \frac{n 2}{n 3}$$

when the light in the light convergence layer 32 is refracted to the interface between the raised portion 321 and the adhesive layer 20, thereby preventing the total reflection of light that is in the light convergence layer 32 and refracted to the interface between the raised portion 321 and the adhesive layer 20, and in turn, allowing light that enters the raised portion 321 to be refracted into the adhesive layer 20. Thus, it is beneficial to prevent the light leakage of each pixel region P (optical device E) of the display panel 100, thereby improving the quality of image display of the display panel 100.

In some embodiments, with continued reference to FIGS. 16 and 17, the following is described by taking an example where the refractive index n3 of the light convergence layer 32 is greater than the refractive index n2 of the adhesive layer 20, the refractive index n3 of the light convergence layer 32 is less than the refractive index n1 of the buffer layer 11, the light convergence portion includes at least one raised portion 321, and the cross section of the raised portion 321 is triangular.

In some examples, with continued reference to FIG. 16, the refractive index n3 of the light convergence layer 32 is greater than the refractive index n2 of the adhesive layer 20, and the incident angle β of the light incident onto the interface between the raised portion 321 and the adhesive layer 20 can be made smaller than the refraction angle. Moreover, since the cross section of the raised portion 321 is triangular, the light that exits from the interface between the raised portion 321 and the adhesive layer 20 may be deflected toward the center of the opening region K (referring to FIG. 15). That is, the raised portion 321 may be used to converge large-angle light in the display panel 100 to prevent problems such as cross-color between adjacent sub-pixel regions and color shift.

In some examples, with continued reference to FIG. 17, since the cross section of the raised portion 321 is triangular, part of light refracted from the raised portion 321 toward the buffer layer 11 to the adhesive layer 20 can be incident onto an adjacent raised portion 321, and then continue to be reflected out of the display panel 100 by the adjacent raised portion 321. The light reflected by the adjacent raised portion 321 may be deflected toward the center of the opening region K (referring to FIG. 15). That is, the raised portion 321 may be used to converge large-angle light in the display panel 100 to prevent the problems such as the cross-color between adjacent sub-pixel regions and color shift.

In some examples, with continued reference to FIG. 17, the base angle α of the raised portion 321 can be set to be greater than or equal to 40°.

Based on this, when the base angle α of the raised portion 321 is equal to or close to 40°, the height of the raised portion 321 may satisfy that the light refracted from the raised portion 321 toward the buffer layer 11 to the adhesive layer 20 can be incident onto an adjacent raised portion 321, and then continue to be reflected out of the display panel 100 by the adjacent raised portion 321. However, some embodiments of the present disclosure are not limited thereto.

In some examples, with continued reference to FIG. 17, the base angle α of the raised portion 321 can be set to be greater than or equal to 60°.

When the base angle α of the raised portion 321 is equal to or close to 60°, the light refracted from the raised portion 321 toward the buffer layer 11 to the adhesive layer 20 may be incident onto an adjacent raised portion 321, and then continue to be reflected out of the display panel 100 by the adjacent raised portion 321. In addition, the existing requirement for manufacturing process may be met. For example, the requirement for manufacturing the raised portion 321 by using a photolithography process or nano-imprinting process may be met. However, some embodiments of the present disclosure are not limited thereto.

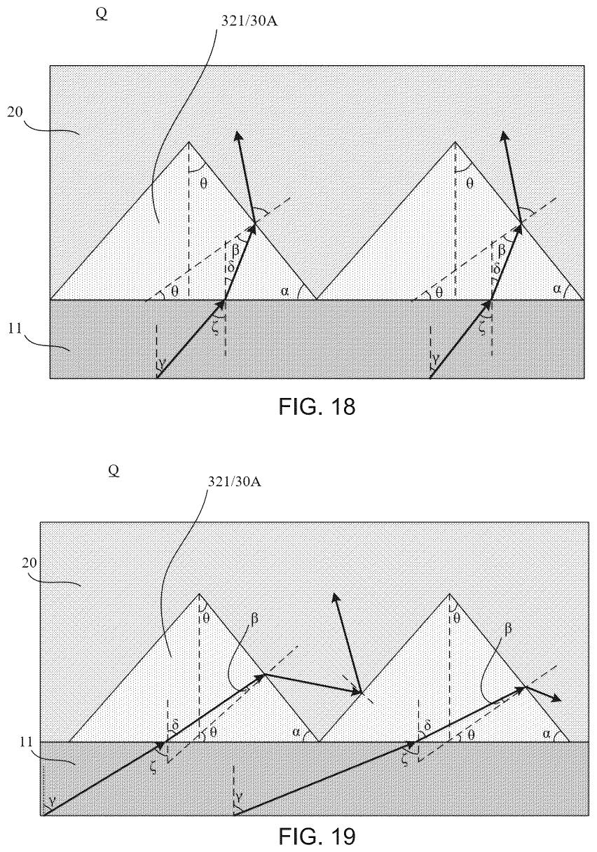

FIG. 18 is yet another light path diagram in the region Q in FIG. 15. FIG. 19 is yet another light path diagram in the region Q in FIG. 15.

In some embodiments, referring to FIGS. 18 and 19, the refractive index n3 of the light convergence layer 32 is greater than the refractive index n1 of the buffer layer 11, i.e., n3>n1>n2. The light convergence portion includes at least one raised portion 321, the cross section of the raised portion 321 is triangular, and the base angle α of the raised portion 321 satisfies

$$arcsin \frac{n 3}{n 1} - arcsin \frac{n 2}{n 3} < α < arcsin \frac{n 3}{n 1} + arcsin \frac{n 2}{n 3} ,$$

where n3 is the refractive index of the light convergence layer 32.

Since the refractive index n3 of the light convergence layer 32 is greater than the refractive index n1 of the buffer layer 11 (that is, when the light enters the light convergence layer 32 from the buffer layer 11, the light enters the medium with the high refractive index from the medium with the low refractive index), no total reflection occurs at the interface between the buffer layer 11 and the raised portion 321. Thus, the light at any angle may be allowed to enter the buffer layer 11 and the raised portion 321 in sequence.

According to the law of refraction, it can be known that n1×sinζ=n3×sinδ. Based on the above description, there is no need to limit the incident angle ζ of light in the buffer layer 11 that is incident onto the raised portion 321, and the value of sinζ should be in a range of 0 to 1, inclusive. Thus, the refraction angle δ of the light refracted into the raised portion 321 should be in a range of 0 to

$$arcsin \frac{n 3}{n 1} ,$$

inclusive, i.e.,

$$δ < arcsin \frac{n 3}{n 1} .$$

With continued reference to FIG. 18, the relationship between various angles in the raised portion 321 can satisfy: 90°−δ=θ+β90°−α+β, α=β+δ. δ is the refraction angle of the light refracted into the raised portion 321, β is the incident angle when the light in the raised portion 321 is incident onto the side face of the raised portion 321, α is the base angle of the raised portion 321, and θ is the supplementary angle of the base angle α of the raised portion 321.

Since the refractive index n3 of the light convergence layer 32 is greater than the refractive index n2 of the adhesive layer 20, the incident angle β needs to be set smaller than the critical angle

$$arcsin \frac{n 2}{n 3} .$$

Based on

$$δ < arcsin \frac{n 3}{n 1} and β < arcsin \frac{n 2}{n 3} ,$$

it can be known that

$$α < arcsin \frac{n 3}{n 1} + arcsin \frac{n 2}{n 3} .$$

With continued reference to FIG. 19, the relationship between various angles in the raised portion 321 can satisfy: 90°−δ=θ−β=90°−α−β, α=δ−β. δ is the refraction angle of the light refracted into the raised portion 321, β is the incident angle when the light in the raised portion 321 is incident onto the side face of the raised portion 321, α is the base angle of the raised portion 321, and θ is the supplementary angle of the base angle α of the raised portion 321.

Since the refractive index n3 of the light convergence layer 32 is greater than the refractive index n2 of the adhesive layer 20, the incident angle β needs to be set smaller than the critical angle

$$arcsin \frac{n 2}{n 3} .$$

Based on

$$δ < arcsin \frac{n 3}{n 1} and β < arcsin \frac{n 2}{n 3} ,$$

it can be known that

$$α > arcsin \frac{n 3}{n 1} - arcsin \frac{n 2}{n 3} .$$

In summary, in the case where the base angle α of the raised portion 321 satisfies

$$arcsin \frac{n 3}{n 1} - arcsin \frac{n 2}{n 3} < α < arcsin \frac{n 3}{n 1} + arcsin \frac{n 2}{n 3} ,$$

the incident angle β can be less than the critical angle

$$arcsin \frac{n 2}{n 3}$$

when the light in the light convergence layer 32 is refracted to the interface between the raised portion 321 and the adhesive layer 20, thereby preventing the total reflection of light that is in the light convergence layer 32 and refracted to the interface between the raised portion 321 and the adhesive layer 20, and in turn, allowing the light that enters the raised portion 321 to be refracted into the adhesive layer 20. Thus, it is beneficial to prevent the light leakage of each pixel region P (optical device E) of the display panel 100, thereby improving the quality of image display of the display panel 100.

In addition, in the case where

$$arcsin \frac{n 3}{n 1} - arcsin \frac{n 2}{n 3} < 0 ,$$

the base angle α of the raised portion 321 satisfies

$$0 < α < arcsin \frac{n 3}{n 1} + arcsin \frac{n 2}{n 3} .$$

In some examples, with continued reference to FIG. 18, the refractive index n3 of the light convergence layer 32 is greater than the refractive index n2 of the adhesive layer 20, and the incident angle β of the light incident onto the interface between the raised portion 321 and the adhesive layer 20 can be made smaller than the refraction angle. Moreover, since the cross section of the raised portion 321 is triangular, the light that exits from the interface between the raised portion 321 and the adhesive layer 20 may be deflected toward the center of the opening region K (referring to FIG. 15). That is, the raised portion 321 may be used to converge large-angle light in the display panel 100 to prevent the problems such as the cross-color between adjacent sub-pixel regions and the color shift.

In some examples, with continued reference to FIG. 19, since the cross section of the raised portion 321 is triangular, part of light refracted from the raised portion 321 toward the buffer layer 11 to the adhesive layer 20 can be incident onto an adjacent raised portion 321, and then continue to be reflected out of the display panel 100 by the adjacent raised portion 321. The light reflected by the adjacent raised portion 321 may be deflected toward the center of the opening region K (referring to FIG. 15). That is, the raised portion 321 may be used to converge large-angle light in the display panel 100 to prevent the problems such as the cross-color between adjacent sub-pixel regions and color shift.

In some examples, the cross section of the raised portion 321 is in a shape of an isosceles triangle. With such arrangement, it is convenient to manufacture the raised portion 321, so as to form the light convergence layer 32. However, some embodiments of the present disclosure are not limited thereto.

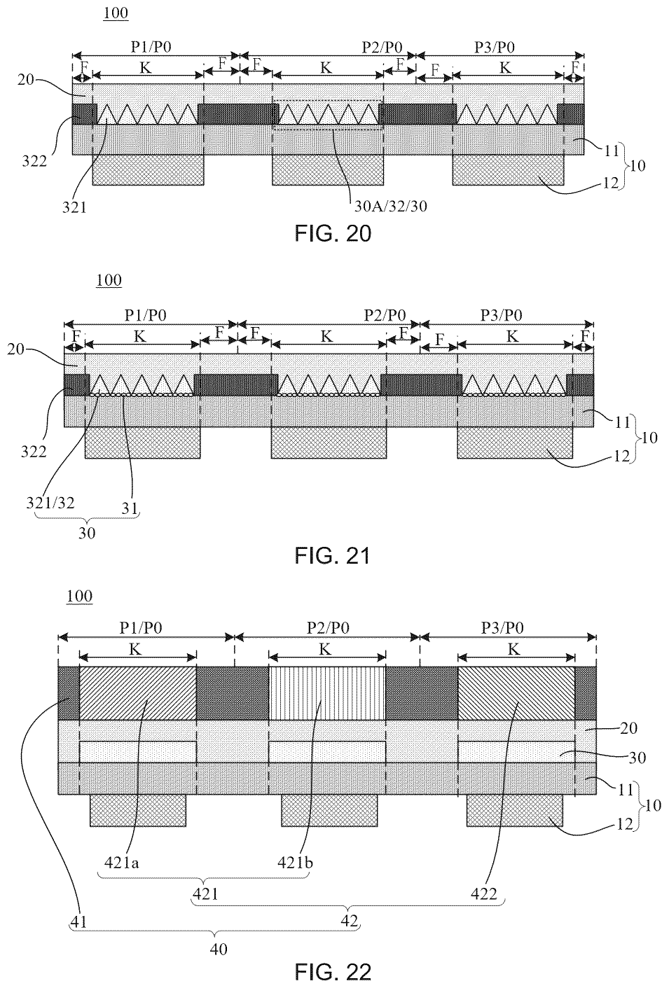

FIG. 20 is a sectional diagram of yet another display panel, in accordance with some embodiments.

In some embodiments, referring to FIG. 20, the display panel 100 further includes a light-shielding portion 322, and the light-shielding portion 322 isolates the plurality of light adjustment portions 30A. A portion of the light-shielding portion 322 is arranged between adjacent light adjustment portions 30A, and the light-shielding portion 322 may be used to prevent the light of the light-emitting unit 12 from entering the opening region K of the adjacent sub-pixel region P0 and prevent the color shift and other problems.

In some examples, a material of the light-shielding portion 322 is carbon black with acrylic resin. However, the embodiments of the present disclosure are not limited thereto. Other materials having adhesiveness and light shielding may also be used to form the light-shielding portion 322.

FIG. 20 is illustrated by taking an example where the light adjustment layer 30 is the light convergence layer 32.

In some examples, referring to FIG. 20, in the case where the light adjustment portion 30A is the light convergence portion in the light convergence layer 32, it is equivalent to arranging the light-shielding portion 322 and the light convergence layer 32 in the same layer, and a portion of the light-shielding portion 322 is arranged between two adjacent light convergence portions (light adjustment portions 30A) in the light convergence layer 32.

In some other examples, in the case where the light adjustment portion 30A is the rough portion in the rough layer 31, it is equivalent to arranging the light-shielding portion 322 and the rough layer 31 in the same layer, and a portion of the light-shielding portion 322 is arranged between two adjacent rough portions (light adjustment portions 30A) in the rough layer 31. FIG. 21 is a sectional diagram of yet another display panel, in accordance with some

embodiments.

In some embodiments, referring to FIG. 21, the light adjustment layer 30 includes the rough layer 31 and the light convergence layer 32. The light convergence layer 32 is located on a side of the rough layer 31 away from the buffer layer 11. That is, the rough layer 31 is arranged between the light convergence layer 32 and the buffer layer 11.

In the case where the rough layer 31 is used to scatter the light emitted by the light-emitting unit 12 to destroy the total reflection of the light at the interface between the portion of the buffer layer 11 and the rough portion in the opening region K, it may be possible to cause part of the light to be scattered to the opening region K of the adjacent sub-pixel region P0 through the rough layer 31, and in turn, easily lead to the problems such as the cross-color and the color shift.

Based on the description of the above embodiments, it can be known that the light convergence layer 32 can converge light to a certain extent. The light convergence layer 32 is arranged on the side of the rough layer 31 away from the buffer layer 11, so that the light convergence layer 32 may not only be used to allow the light to enter the adhesive layer 20, but also play a role in converging the light scattered by the rough layer 31 to a certain extent, thereby preventing the light of the light-emitting unit 12 from entering the opening region K of the adjacent sub-pixel region P0 and preventing the color shift and other problems.

It should be noted that, the rough layer 31 described in any of the above embodiments can be combined with the light convergence layer 32 described in any of the above embodiments to solve the problems of light leakage and color shift of the display panel 100.

In some examples, with continued reference to FIG. 21, in the case where the light adjustment layer 30 includes the rough layer 31 and the light convergence layer 32, the light adjustment portion 30A in the light adjustment layer 30 is composed of the rough portion in the rough layer 31 and the light convergence portion of the light convergence layer 32. The thickness of the light-shielding portion 322 can be set to be approximately equal to the sum of thicknesses of the rough layer 31 and the light convergence layer 32. That is, the surface of the light-shielding portion 322 proximate to the buffer layer 11 can be substantially flush with the surface of the rough layer 31 proximate to the buffer layer 11, and the surface of the light-shielding portion 322 away from the buffer layer 11 can be flush with the surface of the light convergence layer 32 away from the buffer layer 11, which is equivalent to using the light-shielding portion 322 to isolate the plurality of light convergence portions and the plurality of rough portions. The light-shielding portion 322 may be better utilized to prevent the light of the light-emitting unit 12 from entering the opening region K of the adjacent sub-pixel region P0 and prevent the color shift and other problems.

In some examples, referring to FIGS. 20 and 21, the sub-pixel region P0 of the display panel 100 further includes a non-opening region F surrounding the opening regions K. The light-shielding portion 322 at least partially overlaps the non-opening region F.

Since the light adjustment portion 30A is in contact with the light-shielding portion 322, the degree of overlap between the light-shielding portion 322 and the non-opening region F may be defined based on the degree of overlap between the light adjustment portion 30A and the opening region K. Moreover, in the case where the light adjustment portion 30A is in contact with the light-shielding portion 322, it is beneficial to prevent the light from entering the opening region K of the adjacent sub-pixel region P0 through the edge of the light adjustment portion 30A, and prevent the color shift and other problems.

For example, the light-shielding portion 322 substantially overlaps the non-opening region F. Thus, the space of the opening regions K occupied by the light-shielding portion 322 may be reduced to prevent the light-shielding portion 322 from affecting the aperture ratio of the display panel 100.

FIG. 22 is a sectional diagram of yet another display panel, in accordance with some embodiments.

In some embodiments, referring to FIG. 22, the display panel 100 further includes an optical conversion layer 40, and the optical conversion layer 4θ is located on a side of the adhesive layer 20 away from the light adjustment layer 30.

The light-emitting units 12 in different sub-pixel regions P0 can emit light of the same color, and the light of the same color can form light of different colors after being converted by the optical conversion layer 40. Based on this, the plurality of sub-pixel regions P0 of the display panel 100 can emit light of different colors. That is, the first sub-pixel region P1 of the display panel 100 can emit red light, the second sub-pixel region P2 of the display panel 100 can emit green light, and the third sub-pixel region P3 of the display panel 100 can emit blue light, thereby forming the image display.

The optical conversion layer 40 includes a plurality of color conversion portions 42. An orthographic projection of a color conversion portion 42 on the adhesive layer 20 at least partially overlaps an orthographic projection of a light-emitting unit 12 on the adhesive layer 20. With such arrangement, the color conversion portion 42 may be used to adjust the light emitted by the light-emitting unit 12, so that each sub-pixel region P0 emits light of a target color, thereby forming the image display.

In some embodiments, with continued reference to FIG. 22, the color conversion portions 42 include first type color conversion portions 421. The first type color conversion portion 421 is configured to convert the light emitted by the light-emitting unit 12 into light of a target color, so that the sub-pixel region P0 corresponding to the light-emitting unit 12 emits the light of the target color.

In some examples, the first type color conversion portion 421 is a film layer made of an organic material added with a quantum dot (QD) material, and the light conversion effect is achieved through the quantum dot material.

In some examples, the first type color conversion portions 421 include red quantum dot portions 421a and green quantum dot portions 421b. Different quantum dot materials emit light in different wavelength bands after being excited by an excitation light source. For example, the red quantum dot portion 421a converts the light emitted by the light-emitting unit 12 into the red light, and the green quantum dot portion 421b converts the light emitted by the light-emitting unit 12 into the green light.

Based on this, the sub-pixel region P0 where the light-emitting unit 12 corresponding to the red quantum dot portion 421a is located can emit the red light, and the sub-pixel region P0 where the light-emitting unit 12 corresponding to the green quantum dot portion 421b is located can emit the green light, thereby achieving the image display of the display panel 100.

In some embodiments, with continued reference to FIG. 22, the color conversion portions 42 further include second type color conversion portions 422. The second type color conversion portion 422 is configured to allow the light emitted by the light-emitting unit 12 to directly pass through. The second type color conversion portion 422 does not convert the wavelength of the light, and can allow the light emitted by the light-emitting unit 12 to directly pass through, so that the sub-pixel region P0 where the light-emitting unit 12 corresponding to the second type color conversion portion 422 is located may directly emit the color light provided by the light-emitting unit 12.

In some examples, the second type color conversion portion 422 includes a transparent portion with scattering particles. By adding the scattering particles in the transparent portion, the light emitted by the light-emitting unit 12 may continuously refract, reflect and scatter in the second type color conversion portion 422 when passing through the second type color conversion portion 422, and thus the diffusion effect on the light emitted by the light-emitting unit 12 may be achieved.

The light-emitting unit 12 is taken as a blue light-emitting diode chip as an example for

### INTRODUCTION

The red quantum dot portion 421a is located in the first sub-pixel region P1, the green quantum dot portion 421b is located in the second sub-pixel region P2, and the second type color conversion portion 422 is located in the third sub-pixel region P3.

The blue light emitted by the light-emitting unit 12 in the first sub-pixel region P1 can be converted into the red light through the red quantum dot portion 421a, so that the first sub-pixel region P1 emits the red light. The blue light emitted by the light-emitting unit 12 in the second sub-pixel region P2 can be converted into the green light through the green quantum dot portion 421b, so that the second sub-pixel region P2 emits the green light. The blue light emitted by the light-emitting unit 12 in the third sub-pixel region P3 can directly pass through the second type color conversion portion 422, so that the third sub-pixel region P3 emits the blue light.

Based on this, different color conversion portions 42 may be used to allow the first sub-pixel region P1 of the display panel 100 to emit the red light, the second sub-pixel region P2 of the display panel 100 to emit the green light, and the third sub-pixel region P3 of the display panel 100 to emit the blue light, thereby forming the image display.

In some embodiments, with continued reference to FIG. 22, the optical conversion layer 40 further includes a shielding portion 41. The shielding portion 41 isolates the plurality of color conversion portions 42. The shielding portion 41 may be used to prevent the colored lights emitted by two adjacent color conversion portions 42 from interfering with each other, and prevent the cross-color problem.

In some examples, the shielding portion 41 is made of a light-shielding material. For example, the material of the shielding portion 41 is black resin. However, some embodiments of the present disclosure are not limited thereto.

In some embodiments, with continued reference to FIG. 22, an orthographic projection of the color conversion portion 42 on the adhesive layer 20 covers an orthographic projection of the light-emitting unit 12 on the adhesive layer 20.

The light emitted by the light-emitting unit 12 is divergent, Thus, the size of the color conversion portion 42 may be set slightly larger than that of the light-emitting unit 12, and the orthographic projection of the color conversion portion 42 on the adhesive layer 20 covers the orthographic projection of the light-emitting unit 12 on the adhesive layer 20. Based on this, the light emitted by the light-emitting unit 12 may be allowed to enter the color conversion portion 42 as much as possible, so that the color conversion portion 42 may be used to adjust the light and emit the target light. Moreover, it may be possible to prevent the light emitted by the light-emitting unit 12 from entering the adjacent color conversion portion 42, and prevent the color shift and other problems of the display panel 100.

In some other embodiments, the orthographic projection of the color conversion portion

42 on the adhesive layer 20 partially overlaps the orthographic projection of the light-emitting unit 12 on the adhesive layer 20. In yet some other embodiments, the orthographic projection of the color conversion portion 42 on the adhesive layer 20 completely overlaps the orthographic projection of the light-emitting unit 12 on the adhesive layer 20. However, some embodiments of the present disclosure are not limited thereto.

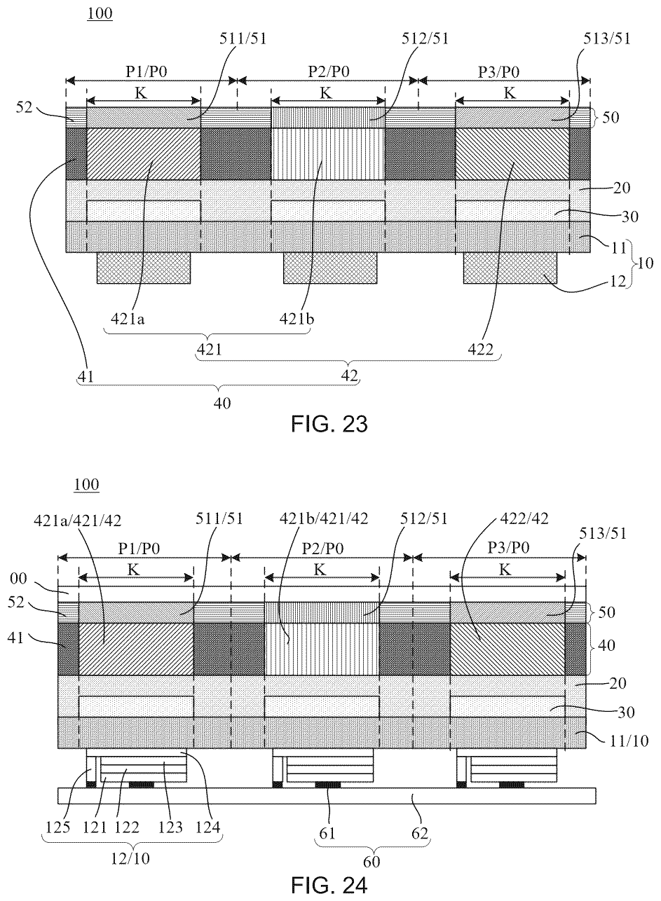

FIG. 23 is a sectional diagram of yet another display panel, in accordance with some embodiments.

In some embodiments, referring to FIG. 23, the display panel 100 further includes a color filter layer. The color filter layer 5θ is located on a side of the optical conversion layer 40 away from the adhesive layer 20. The color filter layer 50 includes a plurality of filter units 51. An orthographic projection of the filter unit 51 on the adhesive layer 20 at least partially overlaps the orthographic projection of the light-emitting unit 12 on the adhesive layer 20. The filter unit 51 may be used to allow the light that is emitted by the light-emitting unit 12 and converted by the corresponding color conversion portion 42 to pass through.

In some examples, the plurality of filter units 51 include first color filter units 511, second color filter units 512 and third color filter units 513.

The first color filter unit 511 corresponds to the red quantum dot portion 421a; the first color filter unit 511 is located in the first sub-pixel region P1, and allows the red light to pass through. The second color filter unit 512 corresponds to the green quantum dot portion 421b; the second color filter unit 512 is located in the second sub-pixel region P2, and allows the green light to pass through. The third color filter unit 513 corresponds to the second type color conversion portion 422; the third color filter unit 513 is located in the third sub-pixel region P3, and allow the blue light to pass through.

In some embodiments, with continued reference to FIG. 23, the color filter layer 50 further includes a black matrix 52, and the black matrix 52 isolates the plurality of filter units 51. The black matrix 52 may be used to prevent the colored lights emitted by two adjacent filter units 51 from interfering with each other, and prevent the cross-color problem.

In some examples, the black matrix 52 is made of a light-shielding material. For example, the material of the black matrix 52 is black resin. However, some embodiments of the present disclosure are not limited thereto.

In some embodiments, with continued reference to FIG. 23, the orthographic projection of the color conversion portion 42 on the adhesive layer 20 covers the orthographic projection of the filter unit 51 on the adhesive layer 20.

By setting the size of the filter unit 51 to be slightly smaller relative to the color conversion portion 42, i.e., by setting the size of the black matrix 52 to be slightly larger relative to the shielding portion 41, the black matrix 52 may be used to effectively shield the light passing through the color conversion portion 42, preventing the light passing through the color conversion portion 42 from being entering the adjacent filter unit 51 and preventing the color shift and other problems of the display panel 100.

In some other embodiments, the orthographic projection of the color conversion portion 42 on the adhesive layer 20 completely overlaps the orthographic projection of the filter unit 51 on the adhesive layer 20. In yet some other embodiments, the orthographic projection of the color conversion portion 42 on the adhesive layer 20 partially overlaps the orthographic projection of the filter unit 51 on the adhesive layer 20. However, some embodiments of the present disclosure are not limited thereto.

FIG. 24 is a sectional diagram of yet another display panel, in accordance with some embodiments.

In some embodiments, referring to FIG. 24, the display panel 100 further includes a driving backplane 60. The driving backplane 60 is located on a side of the light-emitting units 12 away from the buffer layer 11. The driving backplane 60 is bonded to the light-emitting units 12, so that the driving backplane 60 is used to drive the light-emitting units 12 to emit light. Thus, each sub-pixel region P0 of the display panel 100 may emit light.

In the direction in which the driving backplane 60 directs to the buffer layer 11, the light-emitting unit 12 includes: a first electrode 121, a first semiconductor layer 122 electrically connected to the first electrode 121, a light generating layer 123, and a second semiconductor layer 124; and the light-emitting unit 12 further includes a second electrode 125 electrically connected to the second semiconductor layer 124, the second electrode 125 is located on a side of the second semiconductor layer 124 proximate to the driving backplane 60, and on a side of the first electrode 121, the first semiconductor layer 122 and the light generating layer 123 proximate to an adjacent light-emitting unit 12.

In a case where different voltages are respectively applied to the first electrode 121 and the second electrode 125 to form the electric field therebetween, the PN junction with a potential barrier is formed between the first semiconductor layer 122 and the second semiconductor layer 124; carriers in the first semiconductor layer 122 and the second semiconductor layer 124 enter the light generating layer 123 to recombine, and in this case, excess energy is released in a form of light. Thus, electric energy is directly converted into light energy, and the light-emitting unit 12 emits light.

In some examples, the first semiconductor layer 122 is one of an N-type semiconductor layer and a P-type semiconductor layer, and the second semiconductor layer 124 is the other of the N-type semiconductor layer and the P-type semiconductor layer.

For some examples, materials of the first semiconductor layer 122 and the second semiconductor layer 124 are GaN.

In an example where the first semiconductor layer 122 is the P-type semiconductor layer and the second semiconductor layer 124 is the N-type semiconductor layer, the material of the first semiconductor layer 122 is N-GaN, and the material of the second semiconductor layer 124 is P-GaN.

In some examples, the first electrode 121 electrically connected to the first semiconductor layer 122 is an anode of the light-emitting unit 12. The material of the first electrode 121 may be chromium platinum or tin silver. However, some embodiments of the present disclosure are not limited thereto.

In some examples, the second electrode 125 electrically connected to the second semiconductor layer 124 is a cathode of the light-emitting unit 12. The material of the second electrode 125 may be chromium platinum or tin silver. However, some embodiments of the present disclosure are not limited thereto.

In some examples, the light generating layer 123 is a multiple quantum well (MQW) layer.

For example, the structure of the light-emitting unit 12 in any of the embodiments of the present disclosure may be the same as that of the light-emitting unit 21 shown in FIG. 24, and thus, for the structure of the light-emitting unit in other embodiments, reference may be made to the structure of the light-emitting unit 21 shown in FIG. 24. However, some embodiments of the present disclosure are not limited thereto. FIG. 24 only illustrates the light-emitting unit 12 with an inverted Mini LED structure. In some other embodiments, the light-emitting unit 12 may be a Mini LED with an upright structure or a vertical structure.

In some examples, with continued reference to FIG. 24, the driving backplane 60 includes a base substrate 62 and a plurality of connection electrodes 61 located on the base substrate 62. The driving backplane 60 is electrically connected to the electrodes (the first electrodes 121 and the second electrodes 125) of the light-emitting units 12 using the connection electrodes 61.

For example, the first electrode 121 in a light-emitting unit 12 is electrically connected to one of the plurality of connection electrodes 61, and the second electrode 125 in the light-emitting unit 12 is electrically connected to another one of the plurality of connection electrodes 61, so that the light-emitting unit 12 is electrically connected to the driving backplane 60, and the light-emitting unit 12 is driven by the driving backplane 60 to emit light.

In some examples, the base substrate 62 is a flexible substrate. For example, the base substrate 62 is made of an organic material. For example, the material of the base substrate 62 is any one of polyimide (PI), polycarbonate (PC), or polyvinyl chloride (PVC).

In some other examples, the base substrate 62 is a rigid substrate. For example, the rigid substrate is a glass substrate or a polymethyl methacrylate (PMMA) substrate.

In some embodiments, the driving backplane 60 further includes a driving circuit layer. The driving circuit layer may be located between the base substrate 62 and the connection electrodes 61. The driving circuit layer is used to control the connection electrodes 61 to send electrical signals to the first electrode 121 and the second electrode 125 in the light-emitting unit 12, so as to drive the light-emitting unit 12 to emit light.

In some embodiments, with continued reference to FIG. 24, the display panel 100 further includes a cover plate 00, and the cover plate 00 is located on a side of the color filter layer 50 away from the adhesive layer 20. The cover plate 00 may be used to protect film layers under the cover plate 00 from being scratched.

In some examples, the cover plate 00 is made of at least one of transparent polyimide and ultra-thin glass. However, some embodiments of the present disclosure are not limited thereto.

In some embodiments, the display panel 100 further includes an encapsulation layer, and the encapsulation layer is located on the side of the optical conversion layer 40 away from the color filter layer 50. The encapsulation layer may be used to prevent water and oxygen from eroding the optical conversion layer 40 and the color filter layer 50, which may help prolong a service life of the display panel 100.

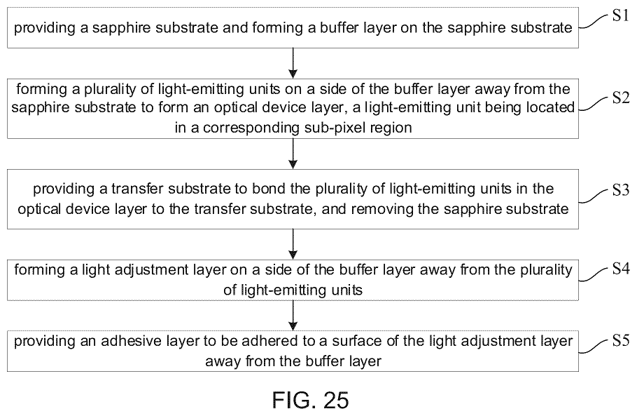

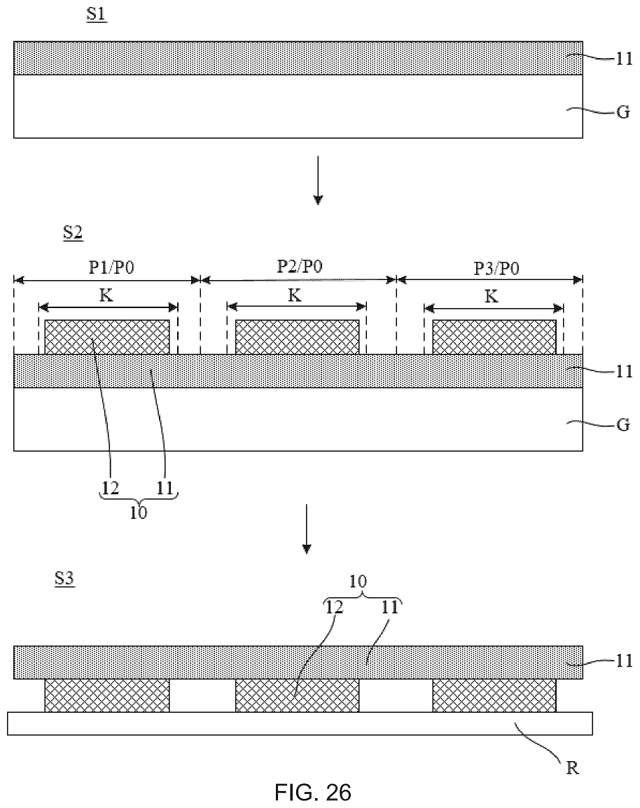

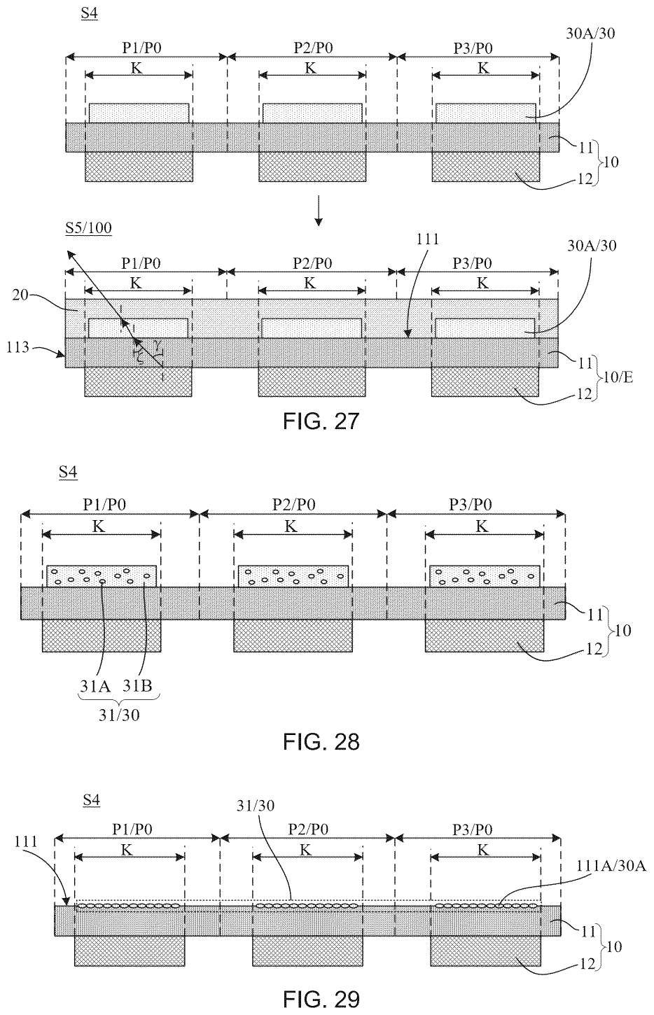

FIG. 25 is a flowchart of a manufacturing method for a display panel, in accordance with some embodiments; FIG. 26 is a structural diagram corresponding to some steps in FIG. 25; and FIG. 27 is a structural diagram corresponding to some other steps in FIG. 25.

Referring to FIGS. 25 to 27, some embodiments of the present disclosure provide a manufacturing method for a display panel 100. The structure of display panel 100 may be referred to FIG. 12. The display panel 100 includes a plurality of pixel regions P, and a pixel region P includes a plurality of sub-pixel regions P0. The sub-pixel region P0 includes an opening region K. The light inside the display panel 100 may be emitted through the opening region K to the outside of the display panel 100, so that each sub-pixel region P0 may emit light. Thus, image display of the display panel 100 is achieved.

In some examples, the plurality of sub-pixel regions P0 include sub-pixel regions P0 with different light-emitting colors.

For example, the plurality of sub-pixel regions P0 are a first sub-pixel region P1, a second sub-pixel region P2 and a third sub-pixel region P3. The first sub-pixel region P1, the second sub-pixel region P2 and the third sub-pixel region P3 emit light of three primary colors. For example, the first sub-pixel region P1 emits red light, the second sub-pixel region P2 emits green light, and the third sub-pixel region P3 emits blue light.

The manufacturing method of the display panel 100 includes the following.

In S1, referring to step S1 in FIG. 26, a sapphire substrate G is provided, and a buffer layer 11 is formed on the sapphire substrate G.

In some examples, a material of the buffer layer 11 includes GaN. However, some embodiments of the present disclosure are not limited thereto.

In S2, referring to step S2 in FIG. 26, a plurality of light-emitting units 12 are formed on a side of the buffer layer 11 away from the sapphire substrate G to form the optical device layer 10, A light-emitting unit 12 being located in a sub-pixel region P0.

In S3, referring to step S3 in FIG. 26, a transfer substrate R is provided to bond the light-emitting units 12 in the optical device layer 10 to the transfer substrate R, and the sapphire substrate G is removed.

In S4, referring to step S4 in FIG. 27, a light adjustment layer 30 is formed on a side of the buffer layer 11 away from the light-emitting units 12.

After the sapphire substrate G is removed in step S3, the buffer layer 11 in the optical device layer 1θ is exposed. Based on this, the light adjustment layer 30 may be formed on the side of the buffer layer 11 away from the light-emitting units 12 in step S4.

In S5, referring to step S5 in FIG. 27, an adhesive layer 20 is provide to be adhered to a surface of the light adjustment layer 30 away from the buffer layer 11.

In step S5, the display panel 100 further includes other film layers. The adhesive layer 20 needs to be used to fix the optical device layer 10 (light adjustment layer 30) and other film layers in the display panel 100. For example, other film layers in the display panel 100 may include an optical conversion layer.

In some examples, referring to step S5 in FIG. 27, in step S5, after the light adjustment layer 30 is formed and fixed to other film layers in the display panel 100 using the adhesive layer 20, the transfer substrate R can be removed.

In some examples, the adhesive layer 20 may be a bonding adhesive layer. For example, the adhesive layer 20 is benzocyclobutene (BCB). In this case, a refractive index of the adhesive layer 20 is approximately 1.56. However, some embodiments of the present disclosure are not limited thereto.

In general, after the optical device layer 1θ is formed, the optical device layer 10 needs to be cut by laser to form independent optical devices E. Subsequently, the independent optical devices E obtained after cutting are transferred into the display panel 100. However, during the cutting process of the optical device layer 10, the buffer layer 11 is cut, which will cause a cutting surface 113 of the buffer layer 11 (i.e., a side surface of each portion of the buffer layer 11 after cutting) to be rough.

In some examples, during the laser cutting process of the optical device layer 10, a light-emitting unit 12 and its corresponding portion of the buffer layer 11 are cut, so that the light-emitting unit 12 and its corresponding portion of the buffer layer 11 form an optical device E.

In some other examples, during the laser cutting process of the optical device layer 10, three light-emitting units 12 and their corresponding portion of the buffer layer 11 are cut, so that the three light-emitting units 12 and their corresponding portion of the buffer layer 11 form an optical device E. In this case, one light-emitting unit 12 is located in one sub-pixel region P0, and one optical device E can be located in one pixel region P.

FIG. 27 takes three light-emitting units 12 in the optical device layer 10 as an example for illustration. In addition, in the case where three light-emitting units 12 and their corresponding portion of the buffer layer 11 are cut during the laser cutting process of the optical device layer 10, the structure of the independent optical device E obtained after cutting can be referred to S5 in FIG. 27. The cutting process will cause the cutting surface 113 of the buffer layer 11 to be rough.

When the light adjustment layer 30 is not provided, the buffer layer 11 is located between the light-emitting units 12 and the adhesive layer 20, and the refractive index of the adhesive layer 20 is less than the refractive index of the buffer layer 11; based on this, when the light entering the buffer layer 11 from the light-emitting units 12 is incident onto an interface between the adhesive layer 20 and the buffer layer 11, the light is incident onto a medium with a low refractive index from a medium with a high refractive index. As a result, part of light is prone to total reflection at the interface between the buffer layer 11 and the adhesive layer 20, and the light cannot enter the adhesive layer. That is, the buffer layer 11 will cause the part of light emitted by the light-emitting units 12 to be unable to exit from the opening region K in each sub-pixel region P0 of the display panel 100, affecting the brightness of each sub-pixel region P0 of the display panel 100. As a result, the quality of image display of the display panel 100 may be reduced.

In addition, during the cutting process of the optical device layer 10, the buffer layer 11 is cut, which will cause the cutting surface 113 of the buffer layer 11 to be rough. Thus, the part of light totally reflected in the buffer layer 11 will continue to be totally reflected until it is incident onto the cutting surface 113 of the buffer layer 11 and exits through the buffer layer 11. The part of light does not exit through the opening regions K, but rather through the cutting surface 113 of the buffer layer 11 (that is, the part of light exits from the edge V of the optical device E (referring to FIG. 3)), which not only affects the brightness of the light-emitting unit 12 in the optical device E, but also causes light leakage at the edge V of the optical device E. Thus, the quality of image display of the display panel 100 is affected.

Based on this, the manufacturing method for the display panel provided in some embodiments of the present disclosure includes step S4 for forming the light adjustment layer 30 on the side of the buffer layer 11 away from the light emitting units 12. The light adjustment layer 30 formed in step S4 is configured such that when light emitted by the light-emitting units 12 enters into the buffer layer 11, at least part of light with a refraction angle greater than or equal to arc sin2/n1 enters the adhesive layer 20 through the light adjustment layer 30, where n1 is the refractive index of the buffer layer 11, and n2 is the refractive index of the adhesive layer 20.

After the light adjustment layer 30 formed in step S4 is added to the display panel 100, the light adjustment layer 30 can be used to allow at least part of light with the refraction angle γ greater than or equal to

$$arcsin \frac{n 2}{n 1} ,$$

enter the adhesive layer 20. That is, at least part of light that would have been totally reflected in the buffer layer 11 can enter the adhesive layer 20 through the light adjustment layer 30, which may mitigate the light leakage problem of the display panel 100 to a certain extent, and in turn, improve the quality of image display of the display panel 100.

In addition, when the light emitted by the light-emitting units 12 enters the buffer layer 11, for light with the refraction angle γ less than

$$arcsin \frac{n 2}{n 1} ,$$

the incident angle ζ of the light incident onto the light adjustment layer 30 is less than the critical angle

$$arcsin \frac{n 2}{n 1} ,$$

so that the light is not able to be totally reflected at the interface between the buffer layer 11 and the light adjustment layer 30, and is able to enter the adhesive layer 20.

Based on this, when the light emitted by the light-emitting units 12 enters the buffer layer 11, for the light with the refraction angle γ less than

$$arcsin \frac{n 2}{n 1} ,$$

and at least part of the light with the refraction angle γ greater than or equal to

$$arcsin \frac{n 2}{n 1} ,$$

they can all continue to enter the adhesive layer 20 and then exit through the opening regions K of the display panel 100, so as to achieve the image display of the display panel 100.

In summary, in the display panel 100 provided in some embodiments of the present disclosure, the light adjustment layer 30 can be disposed on the side of the buffer layer 11 proximate to the adhesive layer 20. The light adjustment layer 30 does not affect the light that has not been totally reflected in the buffer layer 11, so that the light may continue to enter the adhesive layer 20; and the light adjustment layer 30 also allows at least part of the light that would have been totally reflected in the buffer layer 11 to enter the adhesive layer 20, so that the light that is totally reflected in the buffer layer 11 and exits from the cutting surface 113 of the buffer layer 11 may be reduced. Thus, it may be possible to help increase the brightness of each sub-pixel region P0 of the display panel 100, and prevent light leakage of each pixel region P (optical device E) of the display panel 100, thereby improving the quality of image display of the display panel 100.

In some embodiments, with continued reference to FIG. 27, in step S4, the light adjustment layer 30 can be patterned to form a plurality of light adjustment portions 30A, and the light adjustment portion 30A at least partially overlaps the opening region K.

Since a light-emitting unit 12 is located in the opening region K in a sub-pixel region P0, the light emitted by the light-emitting unit 12 exits from the opening region K, and the sub-pixel region P0 emits light. Based on this, the light adjustment layer 30 is patterned into the plurality of light adjustment portions 30A, and the light adjustment portion 30A is arranged to at least partially overlap the opening region K, so that the light adjustment portion 30A overlapping with the opening region K is used to allow at least part of light, which is emitted by the light-emitting unit 12 and has the refraction angle γ greater than or equal to

$$arcsin \frac{n 2}{n 1} ,$$

to enter the adhesive layer 20. Thus, the problem of total reflection of the light emitted by the light-emitting unit 12, and the light emitted by the light-emitting unit 12 can exit from the opening region K of the display panel 100 to ensure the quality of image display of the display panel 100.

Several situations in which the light adjustment portion 30A and the opening region K at least partially overlap have been described in detail above and will not be repeated again here.

FIG. 28 is another structural diagram corresponding to step S4 in FIG. 25.

In some embodiments, referring to FIG. 28, forming the light adjustment layer 30 on the side of the buffer layer 11 away from the light-emitting units 12 in step S4 includes:

forming a rough layer 31 having a plurality of scattering particles 31A on the side of the buffer layer 11 away from the light-emitting units 12 to form the light adjustment layer 30.

In some examples, forming the rough layer 31 includes as follows.

A substrate 31β is formed on the side of the buffer layer 11 away from the light-emitting units 12.

In some examples, the substrate 31β is made of a material with a high transmittance. For example, the substrate 31β is made of at least one of polymethyl methacrylate (PMMA), polystyrene (PS), or polycarbonate (PC).

The plurality of scattering particles 31A are added to the substrate 31B to form the rough layer 31, and the rough layer 31 is used to form the light adjustment layer 30.

In some examples, the scattering particles 31A are made of an organic material. For example, the scattering particles 31A are made of at least one of acrylic acid type, organic silicon type, or polyethylene type. For example, the scattering particles 31A are made of acrylic acid type and organic silicon type.

In some other examples, the scattering particles 31A are made of an inorganic material. For example, the scattering particles 31A are made of at least one of nanometer barium sulfate, silicon dioxide, or calcium carbonate.

Based on this, the plurality of scattering particles 31A in the rough layer 31 may be used to effectively mitigate the problem of total reflection of the light emitted by the light-emitting unit 12 at the interface between the buffer layer 11 and the light adjustment layer 30 (rough layer 31). Thus, it is beneficial to mitigate the light leakage of each pixel region P (optical device E) of the display panel 100, thereby improving the quality of image display of the display panel 100.

FIG. 29 is yet another structural diagram corresponding to step S4 in FIG. 25.

In some embodiments, referring to FIG. 29, forming the light adjustment layer 30 on the side of the buffer layer 11 away from the light-emitting units 12 in step S4 includes: roughening a first surface 111 of the buffer layer 11 away from the light-emitting units 12 to form a plurality of rough regions 111A on the first surface 111, and using portions of the first surface 111 at the plurality of rough regions 111A as a rough layer 31. Thus, the rough layer 31 is used to form the light adjustment layer 30. A portion of the first surface 111 at a rough region 111A is used as one light adjustment portion 30A.

After the first surface 111 of the buffer layer 11 away from the light-emitting units 12 in step S3 is exposed, the first surface 111 of the buffer layer 11 may be roughened in step S4, so that the first surface 111 forms the plurality of rough regions 111A. By using the portions of the first surface 111 at the plurality of rough regions 111A as the rough layer 31, the plurality of rough regions 111A formed by the first surface 111 may be used to scatter a large quantity or even all of the light that would have been totally reflected in the buffer layer 11, so as to make the light enter the adhesive layer 20. That is, the light that is totally reflected in the buffer layer 11 and exits from the cutting surface 113 of the buffer layer 11 may be reduced. Thus, it may be possible to help increase the brightness of each sub-pixel region P0 of the display panel 100, and prevent light leakage of each pixel region P (optical device E) of the display panel 100, thereby improving the quality of image display of the display panel 100.

In addition, since the portions of the first surface 111 at the plurality of rough regions 111A are used as the rough layer 31, after the first surface 111 of the buffer layer 11 proximate to the adhesive layer 20 is roughened, there is no need to add an independent rough layer 31 in the display panel 100, which not only helps save resources, but also helps make the display panel 100 have a light weight and a small thinness.

It should be noted that, FIG. 29 only represents the rough region 111A with multiple elliptical patterns, but does not represent the roughness of the rough region 111A and the structure of the rough region 111A.

In some embodiments, the roughening process performed on the first surface 111 of the buffer layer 11 includes wet roughening. That is, in step S4, the wet roughening is used to form the plurality of rough regions 111A on the first surface 111 of the buffer layer 11.

In some examples, in step S4, acid or alkali is used to etch the first surface 111 of the buffer layer 11, so that the plurality of rough regions 111A are formed on the first surface 111 of the buffer layer 11.

For example, in step S4, hot phosphoric acid (H3PO4) and hot potassium hydroxide (KOH) are used to etch the first surface 111 of the buffer layer 11, so that the plurality of rough regions 111A are formed on the first surface 111 of the buffer layer 11.

In some other embodiments, the roughening process performed on the first surface 111 of the buffer layer 11 includes dry roughening. In step S4, the dry roughening is used to form the plurality of rough regions 111A on the first surface 111 of the buffer layer 11.

For example, in step S4, physical means such as grinding can be used to roughen the first surface 111 of the buffer layer 11 according to a certain rule, so as to form the plurality of rough regions 111A on the first surface 111 of the buffer layer 11.

In some examples, with continued reference to FIG. 29, the roughness of the portions of the first surface 111 at the rough regions 111A is set to be approximately in a range of 10 nm to 100 nm, inclusive.

When the roughness of the portions of the first surface 111 at the rough regions 111A is equal to or close to 10 nm, the roughness of the portions of the first surface 111 at the rough regions 111A is relatively low. Thus, it may be beneficial to simplify the roughening treatment of the first surface 111 of the buffer layer 11 proximate to the adhesive layer 20, and the portions of the first surface 111 at the rough regions 111A may also meet the requirement of destroying the total reflection and making the light scattered. When the roughness of the portions of the first surface 111 at the rough regions 111A is equal to or close to 100 nm, the roughness of the portions of the first surface 111 at the rough regions 111A is relatively high. Thus, the portions of the first surface 111 at the rough regions 111A may more effectively destroy the total reflection of light and make the light scattered. In addition, the existing accuracy requirement for roughening the first surface 111 may also met.

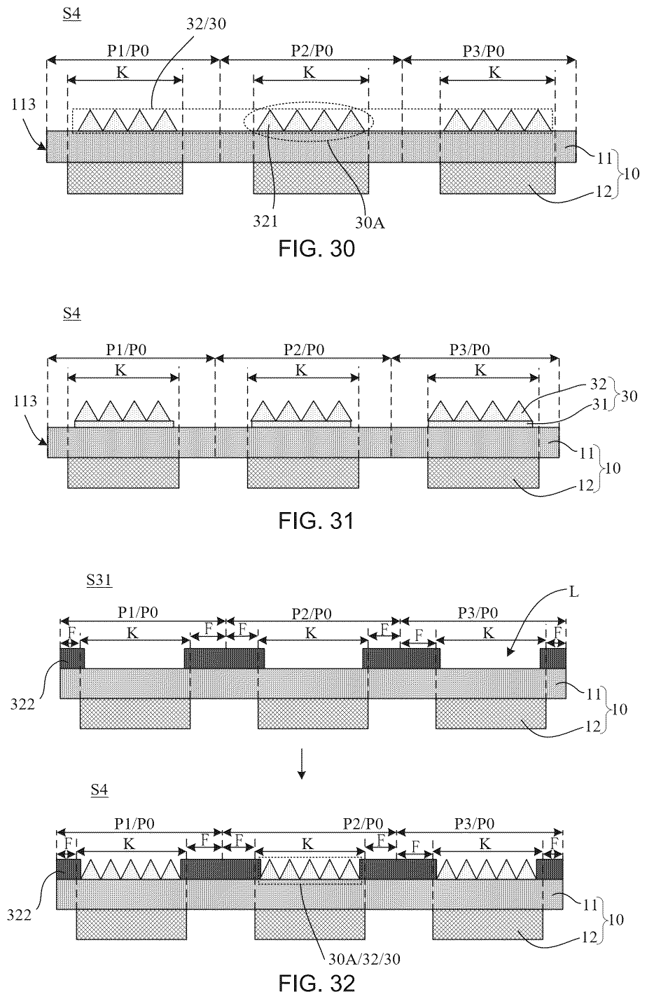

FIG. 30 is yet another structural diagram corresponding to step S4 in FIG. 25.

In some embodiments, referring to FIG. 30, forming the light adjustment layer 30 on the side of the buffer layer 11 away from the light-emitting units 12 in step S4 includes: forming a light convergence layer 32 on the side of the buffer layer 11 away from the light-emitting units 12 to form the light adjustment layer 30.

When the light emitted by the light-emitting units 12 is incident onto the interface between the buffer layer 11 and the light adjustment layer 30, it is equivalent to the light being incident onto the interface between the buffer layer 11 and the light convergence layer 32. By setting the refractive index and structure of the light convergence layer 32, part of light that would have been totally reflected in the buffer layer 11 may enter the adhesive layer 20, reducing the light that is totally reflected in the buffer layer 11 and exits from the cutting surface 113 of the buffer layer 11. Thus, it may be possible to help increase the brightness of each sub-pixel region P0 of the display panel 100, and prevent light leakage of each pixel region P (optical device E) of the display panel 100, thereby improving the quality of image display of the display panel 100.

In some examples, forming the light convergence layer 32 includes: forming a plurality of raised portions 321 on the side of the buffer layer 11 away from the light-emitting units 12, the plurality of raised portions 321 constituting the light convergence layer 32. At least one raised portion 321 constitutes one light adjustment portion 30A, and FIG. 30 only takes four raised portions 321 constituting one light adjustment portion 30A as an example for illustration.

In some examples, a photolithography or nano-imprinting process is used to form the plurality of raised portions 321 on the side of the buffer layer 11 away from the light-emitting units 12, and the plurality of raised portions 321 constitute the light convergence layer 32. However, some embodiments of the present disclosure are not limited thereto.

In some examples, the cross section of the raised portion 321 may be semicircular or triangular. However, some embodiments of the present disclosure are not limited thereto, as long as the raised portion 321 has a structure protruding toward the adhesive layer 20.

When the cross section of the raised portion 321 is triangular, the description for limitations on the structure of the raised portion 321 and the refractive index of the light convergence layer 32 is similar to the above description of the light convergence layer 32 in the display panel 100, and details are not repeated here.

FIG. 31 is yet another structural diagram corresponding to step S4 in FIG. 25.

In some embodiments, referring to FIG. 31, forming the light adjustment layer 30 on the side of the buffer layer 11 away from the light-emitting units 12 in step S4 includes:

forming the rough layer 31 on the side of the buffer layer 11 away from the light-emitting units 12; and

forming the light convergence layer 32 on a side of the rough layer 31 away from the light-emitting units 12, so as to form the light adjustment layer 30.

Based on the description of the above embodiments, it can be known that the light convergence layer 32 can converge light to a certain extent. The light convergence layer 32 is arranged on the side of the rough layer 31 away from the buffer layer 11, so that the light convergence layer 32 may not only be used to allow the light to enter the adhesive layer 20, but also play a role in converging the light scattered by the rough layer 31 to a certain extent, thereby preventing the light of the light-emitting unit 12 from entering the opening region K of the adjacent sub-pixel region P0 and preventing the color shift and other problems.

It should be noted that, the rough layer 31 described in any of the above embodiments can be combined with the light convergence layer 32 described in any of the above embodiments to solve the problems of light leakage and color shift of the display panel 100.

FIG. 32 is a structural diagram of some steps of a manufacturing method of a display panel, in accordance with some embodiments.

In some examples, with continued reference to FIG. 20 or 21, the sub-pixel region P0 of the display panel 100 further includes a non-opening region F surrounding the opening regions K. The display panel 100 further includes a light-shielding portion 322. Based on this, in the manufacturing method of the display panel, before forming the light adjustment layer 30 in step

S4 and after step S3, the following step is included.

In S31, the light-shielding portion 322 is formed on the side of the buffer layer 11 away from the light-emitting units 12, the light-shielding portion 322 including a plurality of hollow regions L. The light-shielding portion 322 can at least partially overlap the non-opening region F.

In step S4 after step S31, the plurality of light adjustment portions 30A in the light adjustment layer 30 are formed on the buffer layer 11 in the hollow regions L.

Based on this, the light-shielding portion 322 may be used to isolate the plurality of light adjustment portions 30A, and the light adjustment portion 30A at least partially overlaps the opening region K. The light-shielding portion 322 may be used to prevent the light of the light-emitting unit 12 from entering the opening region K of the adjacent sub-pixel region P0 and prevent the color shift and other problems.

In some other embodiments, a surface of the light-shielding portion 322 proximate to the light adjustment portion 30A is in contact with a surface of the light adjustment portion 30A proximate to the light-shielding portion 322. For example, in a thickness direction of the light adjustment layer 30, a height of the surface of the light-shielding portion 322 proximate to the light adjustment portion 30A is greater than or equal to that of the surface of the light adjustment portion 30A proximate to the light-shielding portion 322. Thus, it may be possible to prevent light from entering the opening region K of the adjacent sub-pixel region P0 through the edge of the light adjustment portion 30A and prevent the color shift and other problems.

The structures of the light adjustment portion 30A and the light adjustment layer 30 may be the structures described in any of the above embodiments. FIG. 32 only illustrates an example where the light adjustment layer 30 is the light convergence layer 32, and the light adjustment portion 30A is the light convergence portion.

In some embodiments, after removing the transfer substrate R in step S5, the method further includes step S6. In S6, a driving backplane is provided, and the light-emitting units 12 in the optical device layer 10 are bonded to the driving backplane. The driving backplane is used to drive each light-emitting unit 12 in the optical device layer 10, so that each sub-pixel region P0 of the display panel 100 emits light, achieving the image display.

In some embodiments, after step S4 and before step S5, the manufacturing method of the display panel 100 further includes step S41.

In S41, a glass substrate is provided, and an optical conversion layer is formed on the glass substrate. In some examples, the glass substrate is also used as a glass cover of the display panel 100. The glass substrate may serve as a substrate and provide support, which facilitates the formation of the optical conversion layer on the glass substrate. Moreover, after the display panel 100 is manufactured, the glass substrate can also be used as the glass cover 00 of the display panel 100, which may protect the display panel 100 and prevent its internal film layers from being scratched.

Based on this, in step S5, the adhesive layer 20 is provided, and the adhesive layer 20 is disposed between the light adjustment layer 30 and the optical conversion layer to fix the light adjustment layer 30 and the optical conversion layer, so that the optical device layer 10 and the optical conversion layer are relatively fixed. Thus, the optical conversion layer is used to convert the same color light emitted by the light-emitting units 12 in the optical device layer 10 into light of different colors, achieving the image display of the display panel 100.

In summary, some embodiments of the present disclosure provide the display panel 100 and manufacturing method therefor, and a display apparatus 200. The display apparatus 200 includes the display panel 100. The light adjustment layer 30 is disposed in the display panel 100. The light adjustment layer 30 is disposed on the side of the buffer layer 11 in the display panel 100 proximate to the adhesive layer 20. The light adjustment layer 30 does not affect the light that has not been totally reflected in the buffer layer 11, so that the light may continue to enter the adhesive layer 20; and the light adjustment layer 30 also allows at least part of light that would have been totally reflected in the buffer layer 11 to enter the adhesive layer 20, so that the light that is totally reflected in the buffer layer 11 and exits from the cutting surface 113 of the buffer layer 11 may be reduced. Thus, it may be possible to help increase the brightness of each sub-pixel region P0 of the display panel 100, and prevent light leakage of each pixel region P (optical device E) of the display panel 100, thereby improving the quality of image display of the display panel 100. On this basis, since the display apparatus 200 includes the display panel 100 in any of the above embodiments, the display apparatus 200 has all the beneficial effects described above.

The foregoing descriptions are merely specific implementations of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure should be determined by the protection scope of the claims.

What is claimed is:

1. A display panel having a plurality of sub-pixel regions, a sub-pixel region including an opening region, wherein the display panel comprises:
an optical device layer, wherein the optical device layer includes a buffer layer and a plurality of light-emitting units, a light-emitting unit is located in an opening region of a corresponding sub-pixel region, and the buffer layer is located on a light-exit surface of the plurality of light-emitting units;
an adhesive layer located on a side of the buffer layer away from the plurality of light-emitting units, a refractive index of the adhesive layer being less than a refractive index of the buffer layer; and
a light adjustment layer located on the side of the buffer layer proximate to the adhesive layer, wherein the light adjustment layer is configured such that when light emitted by the plurality of light-emitting units enters into the buffer layer, at least part of light with a refraction angle greater than or equal to
$$arcsin \frac{n 2}{n 1}$$
enters the adhesive layer through the light adjustment layer;
where n1 is the refractive index of the buffer layer, and n2 is the refractive index of the adhesive layer.

2. The display panel according to claim 1, wherein the light adjustment layer includes a plurality of light adjustment portions, and a light adjustment portion at least partially overlaps a corresponding opening region.

3. The display panel according to claim 2, wherein the light adjustment portion is located in the corresponding opening region.

4. The display panel according to claim 1, wherein the light adjustment layer includes a rough layer.

5. The display panel according to claim 4, wherein the rough layer includes a plurality of scattering particles.

6. The display panel according to claim 4, wherein the buffer layer includes a first surface proximate to the adhesive layer; the first surface includes a plurality of rough regions, and the plurality of rough regions are used as the rough layer.

7. The display panel according to claim 4, wherein a roughness of the rough layer is approximately in a range of 10 nm to 100 nm, inclusive.

8. The display panel according to claim 1, wherein the light adjustment layer includes a light convergence layer.

9. The display panel according to claim 1, wherein the light adjustment layer includes a rough layer and a light convergence layer, and the light convergence layer is located on a side of the rough layer away from the buffer layer.

10. The display panel according to claim 8, wherein a refractive index of the light convergence layer is greater than that of the adhesive layer, and the refractive index of the light convergence layer is less than that of the buffer layer.

11. The display panel according to claim 10, wherein the light convergence layer includes at least one raised portion, and a cross section of a raised portion is triangular; and a base angle α of the raised portion satisfies:
$$arcsin \frac{n 2}{n 1} - arcsin \frac{n 2}{n 3} < α < arcsin \frac{n 2}{n 1} + arcsin \frac{n 2}{n 3} ;$$
where n3 is the refractive index of the light convergence layer.

12. The display panel according to claim 8, wherein a refractive index of the light convergence layer is greater than that of the buffer layer;
the light convergence layer includes at least one raised portion, and a cross section of a raised portion is triangular; and a base angle α of the raised portion satisfies:
$$arcsin \frac{n 3}{n 1} - arcsin \frac{n 2}{n 3} < α < arcsin \frac{n 3}{n 1} + arcsin \frac{n 2}{n 3} ;$$
where n3 is the refractive index of the light convergence layer.

13. The display panel according to claim 2, further comprising a light-shielding portion, wherein the light-shielding portion isolates the plurality of light adjustment portions.

14. The display panel according to claim 1, further comprising an optical conversion layer, wherein
the optical conversion layer is located on a side of the adhesive layer away from the light adjustment layer;
the optical conversion layer includes a shielding portion and a plurality of color conversion portions, and the shielding portion isolates the plurality of color conversion portions; an orthographic projection of a color conversion portion on the adhesive layer at least partially overlaps an orthographic projection of a corresponding light-emitting unit on the adhesive layer.

15. The display panel according to claim 14, wherein the plurality of color conversion portions include first type color conversion portions and second type color conversion portions; a first type color conversion portion is configured to convert light emitted by a corresponding light-emitting unit into light of a target color; and a second type color conversion portion is configured to allow light emitted by a corresponding light-emitting unit to directly pass through.

16. The display panel according to claim 14, further comprising a color filter layer, wherein
the color filter layer is located on a side of the optical conversion layer away from the adhesive layer; the color filter layer includes a plurality of filter units and a black matrix, and the black matrix isolates the plurality of filter units;
an orthographic projection of a filter unit on the adhesive layer at least partially overlaps an orthographic projection of a corresponding light-emitting unit on the adhesive layer.

17. The display panel according to claim 16, wherein the orthographic projection of the color conversion portion on the adhesive layer covers the orthographic projection of the filter unit on the adhesive layer.

18. A manufacturing method for a display panel, wherein the display panel has a plurality of sub-pixel regions, and a sub-pixel region includes an opening region;
the manufacturing method includes:
providing a sapphire substrate;
forming a buffer layer on the sapphire substrate;
forming a plurality of light-emitting units on a side of the buffer layer away from the sapphire substrate to form an optical device layer, wherein a light-emitting unit is located in a corresponding sub-pixel region;
providing a transfer substrate to bond the plurality of light-emitting units in the optical device layer to the transfer substrate;
removing the sapphire substrate;
forming a light adjustment layer on a side of the buffer layer away from the plurality of light-emitting units; and
providing an adhesive layer to be adhered to a surface of the light adjustment layer away from the buffer layer, wherein
the light adjustment layer is configured such that when light emitted by the plurality of light-emitting units enters into the buffer layer, at least part of light with a refraction angle greater than or equal to
$$arcsin \frac{n 2}{n 1}$$
enters the adhesive layer through the light adjustment layer; where n1 is the refractive index of the buffer layer, and n2 is the refractive index of the adhesive layer.

19. The manufacturing method according to claim 18, wherein forming the light adjustment layer on the side of the buffer layer away from the plurality of light-emitting units includes:
forming a rough layer having a plurality of scattering particles on the side of the buffer layer away from the plurality of light-emitting units to form the light adjustment layer; or
roughening a first surface of the buffer layer away from the plurality of light-emitting units to form a plurality of rough regions on the first surface, wherein the plurality of rough regions are used as a rough layer, and the rough layer is used to form the light adjustment layer; or
forming a light convergence layer on the side of the buffer layer away from the plurality of light-emitting units to form the light adjustment layer; or
forming a rough layer on the side of the buffer layer away from the plurality of light-emitting units; and forming a light convergence layer on a side of the rough layer away from the plurality of light-emitting units, so as to form the light adjustment layer.

20. A display apparatus, comprising the display panel according to claim 1.
